(19) United States
(12) Patent Application Publication
(10) Pub. No.: US 2015/0108974 A1
(43) Pub. Date: Apr. 23, 2015

(54) MAGNETOMETER

(71) Applicant: INSTITUTE OF GEOLOGICAL AND NUCLEAR SCIENCES LIMITED, Lower Hutt (NZ)

(72) Inventors: John Vedamuthu Kennedy, Gracefield (NZ); Jerome Leveneur, Gracefield (NZ); Grant Victor McLelland Williams, Gracefield (NZ); Richard John Futter, Gracefield (NZ)

(73) Assignee: INSTITUTE OF GEOLOGICAL AND NUCLEAR SCIENCES LIMITED, Lower Hutt (NZ)

(21) Appl. No.: 14/391,922

(22) PCT Filed: Apr. 12, 2013
(86) PCT No.: PCT/NZ2013/000064

§ 371 Date: Oct. 10, 2014

(30) Foreign Application Priority Data
Apr. 12, 2012 (NZ) 599332

(51) Int. Cl. G01R 33/09

(52) U.S. Cl. CPC G01R 33/09
USPC 324/252

(57) ABSTRACT

A magnetometer (100) for measuring an external magnetic field has at least one core (102), two excitation coils (106a), (106b), and a pick-up coil (104). The at least one core (102) has a magnetoresistance property measurable in response to the external magnetic field (111). Each excitation coil (106a), (106b) is near or around opposite ends of the core (102) or near or around a respective core. The excitation coils (106a), (106b) are configured to be driven by an alternating current to partially saturate a magnetisation of the core during part of the AC cycle. The pick-up coil (104) is near or around at least a portion of the core (102) and the excitation coils (106a), (106b). The pick-up coil (104) is configured to carry a signal induced at least in the presence of the external magnetic field (111). The induced signal is measurable in response to the external magnetic field (111).

### FIELD OF THE INVENTION

The present invention relates generally to a magnetometer for performing wide dynamic range magnetic field measurements, and the application of such a magnetometer in, for example, magneto-electronic devices such as magnetic field sensors and current sensors.

### BACKGROUND

Precise magnetic field measurements are necessary in a wide range of fields and applications ranging from navigation to accelerator technology and materials science. Such measurements may also be required for measuring current flowing through a conductor without contacts, for example in the case of batteries, solar cells or fuel cells. For these and other applications, the dimensions of the sensors are limited.

Many different technologies have been developed based on different physical principles such as electromagnetic induction, Hall effect, Nuclear precession, Faraday rotation, Superconducting Quantum Interference Device (SQUID), magnetoresistance, giant magnetoimpedance, and fluxgates. These devices provide excellent sensitivities in various different magnetic field ranges. However, there is no suitable single magnetic field sensor that is capable of measuring a wide range of magnetic fields (from 1 nT up to 30 T for example). Commercial Giant Magnetoresistance (GMR) and Anisotropic Magnetoresistance (AMR) sensors are small and can measure small magnetic fields but they are limited to ˜50 mT due to saturation of the magnetic material. SQUIDs are also small but they are expensive and they cannot be used to measure large fields. Sensors that rely on nuclear precession are also expensive, cannot be miniaturized, and are not capable of measuring small magnetic fields. Bulk Hall sensors are the most common magnetic sensor and can be miniaturised, but are not capable of measuring small magnetic fields. While 2D electron gas Hall sensors are more sensitive than bulk Hall sensors (by a factor of ˜10), these sensors experience non-linearity at moderate fields.

The most versatile technology is based on induction search coils, which can be designed specifically for different applications. However, the coils can only measure AC magnetic fields and the sensitivity decreases as the size is reduced. Some applications, such as power control for batteries, ion transport and accelerator systems, require the ability to precisely measure a magnetic field, either from current flowing through a wire or an electromagnet, over a wide range of magnetic field from 1 nT to 1 T. At present, this can only be achieved by using several complementary sensors.

Fluxgate magnetometers can measure low magnetic fields and DC magnetic fields and they can be miniaturised. One simple construction uses a high permeability, low hysteresis magnetic core, two excitation coils that are each wound on each core, and a pick-up coil wound over both cores. In some cases and depending on the application, different geometries are used that include a toroidal or cross shaped core. Synchronous AC excitation signals are driven through the excitation coils so that the sum of the magnetic fields from both cores is zero when there is no external applied magnetic field. It is only when an external field is applied on the axis of the pick-up coil that the net magnetic field in the pickup coil is non-zero and time varying and this leads to a signal that is generated in the pick-up coil with twice the excitation frequency. The amplitude and shape of the signal from the pick-up coil is dependent on the external magnetic field. The pick-up signal is filtered and amplified, and the amplitude and phase of the signal provides the direction and amplitude of the external magnetic field. Lock-in amplifier systems are typically used to detect the signal. Fluxgate magnetometers can provide low magnetic field measurements (down to several 10 pT). However, they cannot measure high magnetic fields (above several 100 pT) because the magnetic core becomes saturated, the magnetization in non-linear, or the hysteresis effects become significant.

Miniature fluxgate magnetometers have been developed using many different geometries with the fabrication process typically involving PCB or micro-fabrication.

Superparamagnetic materials, in particular superparamagnetic nanomaterials, have been shown to be particularly effective for use as cores in miniature fluxgates. Indeed, the materials show appropriate low hysteresis in their magnetization, high permeability and low saturation field.

Low magnetic fields can be measured with an AMR fluxgate magnetometer. P. D. Dimitropoulos describes a hybrid fluxgate technology where the pick-up coil is replaced by an AMR sensor to enable lower magnetic fields to be measured [P. D. Dimitropoulos, Sensors and Actuators A 107 (2003) 238-247]. Hybrid magnetometers are similar to standard fluxgate magnetometers because the excitation fields oppose each other and no signal is present without an external magnetic field. Such fluxgate magnetometers have shown high sensitivity for low magnetic field measurements with potential for faster response than standard fluxgate magnetometers. Furthermore, they usually have low dimensions and can be integrated into microelectronic devices. However, the technology remains limited in magnetic field range. In particular, large field measurements are not possible due to the low field saturation, non-linearity, and hysteresis of the magnetization in the AMR material (typically >200 μT).

Large magnetoresistances can provide an excellent method to measure a wide range of magnetic fields. Indeed, AMR, GMR, and magnetic tunneling junction (MD) can probe low magnetic fields (down to several nT) with high sensitivity. However, saturation of the magnetic material limits their use to fields of less than ˜0.1 T. Other magnetoresistance types, including avalanche breakdown, spin injection magnetoresistance, and geometrical magnetoresistance, have shown high sensitivity for large magnetic fields (>0.5 T). In particular, nanostructured materials such as pressed Fe nanopowder, Fe nanoparticles on SiO₂ and nanogranular Fe:Al₂O₃ thin films have shown large positive magnetoresistances with linear behaviour at high field. These nanomaterials present interesting properties for magneto-electronic devices for magnetic field sensing such as the absence of hysteresis and low temperature drift. However, no single magnetoresistance technology has been shown to provide an accurate magnetic field measurement for low to high fields.

Non-contact current sensing also relies on the measurement of the magnetic field that is generated by an electrical current flowing through a conductor. For this purpose, soft magnetic materials are used as magnetic flux concentrators that enclose the conductor and which usually comprise a gap in which the concentrated magnetic flux is measured. The actual magnetic flux measurement at this point is performed by means of a Hall effect, a magnetoresistance or a fluxgate sensor. However, and for the same reasons as mentioned above, the range of magnetic fields and hence the detected current range, is limited.

Accordingly, it is an object of the present invention to overcome the disadvantages of the above mentioned methods and to provide a magnetometer with a wide dynamic range and/or to at least provide the public with a useful choice.

### SUMMARY OF THE INVENTION

According to a first aspect, the present invention provides a magnetometer for measuring an external magnetic field, comprising:
at least one core having a magnetoresistance property being measurable in response to the external magnetic field;
at least one excitation coil near or around the core or at least one of the cores, the excitation coil(s) being configured to be driven by an alternating current to partially saturate a magnetisation of the core(s) during part of the AC cycle; and
at least one pick-up coil near or around at least a portion of the core(s) and the excitation coil(s), the pick-up coil(s) being configured to carry a signal induced at least in the presence of the external magnetic field, the induced signal being measurable in response to the external magnetic field.

In one embodiment, the magnetometer comprises one core and one excitation coil near or around the core.

In an embodiment, the magnetometer comprises two or more excitation coils, each excitation coil near or around opposite ends of the core or near or around a respective core. In an embodiment, the magnetometer comprises one core and two excitation coils, each excitation coil being near or around opposite ends of the core. In an alternative embodiment, the magnetometer comprises a first core, a second core, a first excitation coil and a second excitation coil, wherein the first excitation coil is near or around the first core, and the second excitation coil is near or around the second core. In an alternative embodiment, the magnetometer comprises a first core, a second core, a first pair of excitation coils, and a second pair of excitation coils, wherein the first pair of excitation coils is near or around opposite ends of the first core and the second pair of excitation coils is near or around opposite ends of the second core.

In an embodiment, the magnetometer comprises two or more excitation coils, and the excitation coils are configured to induce a substantially negligible total magnetisation of the core(s) in an absence of the external magnetic field.

In an alternative embodiment, the magnetometer comprises two or more excitation coils, and the excitation coils are configured to induce an alternating magnetisation of the core in an absence of the external magnetic field. In a further embodiment, the excitation coils are configured to induce a signal in the pick-up coil(s) that comprises positive and negative responses, and the external magnetic field results in a change in time interval between the negative and positive responses in the induced signal. In an alternative embodiment, the excitation coils are configured to induce a signal in the pick-up coil that comprises a series of pulses, and a change in peak voltage of one or more of the pulses represents the external magnetic field.

In the embodiment where the magnetometer comprises a first core, a second core and two or four excitation coils, in the absence of an external magnetic field, a magnetic field induced by the excitation coil(s) near or around the first core is opposite to a magnetic field induced by the excitation coil(s) near or around the second core, a sum of the magnetic fields in the first and second core being substantially zero in the absence of the external magnetic field, wherein the external magnetic field results in the sum of the magnetic fields in the first and second core being non-zero and/or time-varying.

In an embodiment, the magnetometer comprises three cores and six excitation coils for magnetic field measurements in three axes, a respective pair of excitation coils around or near one of the respective cores. In a further embodiment, the cores are positioned orthogonally to each other core, and magnetic field measurements from the core in an axis represent the external magnetic field in that axis.

In an alternative embodiment, the magnetometer comprises six cores and twelve excitation coils for magnetic field measurements in three axes, wherein two excitation coils are around or near each of the cores. In a further embodiment, three pairs of cores are positioned orthogonally to each other pair, and magnetic field measurements from two respective cores in an axis represent the external magnetic field in that axis.

In an embodiment, the magnetometer comprises a plurality of pick-up coils, and each pick-up coil near or around different portions of the core(s) and the excitation coil(s).

In an embodiment, the core(s) comprise(s) a high permeability superparamagnetic magnetoresistive material comprising nanoparticles, and the material exhibits electron spin polarisation for negative magnetoresistances, which arises from spin tunneling between nanoparticles over a range of operating temperatures. In a further embodiment, the high permeability superparamagnetic magnetoresistive material comprises nanoparticles chosen from the group consisting of iron, nickel, cobalt, their alloys and oxides, and mixtures thereof showing ferromagnetic behaviour at room temperature. In a further embodiment, the high permeability superparamagnetic magnetoresistive material comprises nanoparticles of a ferromagnetic ferrite. In a further embodiment, the ferromagnetic ferrite is chosen from the group consisting of ZnFe₂O₄, BaFe₁₂O₉, and Ni_{0.5}Zn_{0.5}Fe₂O₄.

In an embodiment, the core(s) comprise(s) a blocking temperature substantially below an operating temperature range and a Curie temperature substantially above the operating temperature range. In a further embodiment, the blocking temperature of the core(s) is below about 200 K and the Curie temperature of the core(s) is above about 313 K. In a further embodiment, the relative permeability of the core(s) is greater than 1. In a further embodiment, the relative permeability of the core(s) is greater than 50. In a further embodiment, the relative permeability of the core(s) is greater than 1000.

In an embodiment, the core(s) comprise(s) a pressed nanoparticle powder. In a further embodiment, the pressed nanoparticle powder comprises core/shell nanoparticles. In a preferred embodiment, the pressed nanoparticle powder comprises iron (II, III) oxide (Fe₃O₄) nanoparticles.

In another embodiment, the core(s) comprise(s) a magnetoresistive film containing nanoparticles. In a further embodiment, the nanoparticles are synthesised on or embedded in a surface of a substrate of the film. In a further embodiment, the film comprises silicon dioxide and iron nanoparticles. Preferably, the magnetoresistive film containing nanoparticles is a thin film. Preferably, where the core is the thin film, the excitation coil(s) and/or the pick-up coil(s) is/are near the thin film. Alternatively, the magnetoresistive film containing nanoparticles may be a thick film. Preferably, where the core is the thick film, the excitation coil(s) and/or the pick-up coil(s) is/are near or around the thick film.

In an embodiment, the signal from the pick-up coil(s) is used for measuring external magnetic fields below a defined magnetic field threshold and the magnetoresistance of the core(s) is used for measuring external magnetic fields above the defined magnetic field threshold.

In an embodiment, the signal from the pick-up coil(s) is used for measuring external magnetic field values down to about 0.1 nT. In a further embodiment, the magnetoresistance of the core(s) is used for measuring external magnetic field values up to at least about 7 T. In a further embodiment, the magnetoresistance of the core(s) is used for measuring external magnetic field values up to at least about 12 T. In a further embodiment, the magnetoresistance of the core(s) is used for measuring external magnetic field values up to at least about 30 T.

In an embodiment, the defined magnetic field threshold is a saturation field of the pick-up coil(s), which is the field at which the signal from the pick-up coil(s) begins to show a saturated response. In this embodiment, the magnetoresistance of the core(s) is used for measuring external magnetic field values greater than the saturation field of the signal from the pick-up coil(s), and the signal from the pick-up coil(s) is used for measuring external magnetic field values less than the saturation field of the signal from the pick-up coil(s) while the pick-up coil(s) is/are on its linear and non-linear regime up to the saturation field. In a further embodiment, the defined magnetic field threshold is about 1.5 mT. In a further embodiment, the signal from the pick-up coil(s) saturates at 1.5 mT. In a further embodiment, the signal from the pick-up coil(s) is used for measuring external magnetic field values less than about 1.5 mT. In a further embodiment, the signal from pick-up coil(s) is used for measuring the external magnetic field values in the range of about 0.1 nT to about 1.5 mT. In a further embodiment, the magnetoresistance of the core(s) is used for measuring external magnetic fields greater than 1.5 mT. Preferably, the magnetoresistance of the core(s) is used for measuring external magnetic field values in the range of about 1.5 mT to about 7 T. In a further embodiment, the magnetoresistance of the core(s) is used for measuring external magnetic fields up to at least about 12 T. In a further embodiment, the magnetoresistance of the core(s) is used for measuring external magnetic fields up to at least about 30 T.

In another embodiment, the defined magnetic field threshold is the non-linear field, which is the field at which the signal from the pick-up coil(s) switches from a linear response to a non-linear response. In this embodiment, the magnetoresistance of the core(s) is used for measuring external magnetic field values greater than the non-linear field of the signal from the pick-up coil(s), and the signal from the pick-up coil(s) is used for measuring external magnetic field values less than the non-linear field of the signal from the pick-up coil(s) while the pick-up coil(s) is/are on its linear regime. In an embodiment, the defined magnetic field is about 0.5 mT. In a further embodiment the signal from the pick-up coil(s) is linear with less than 1% non-linearity up to 0.5 mT. In a further embodiment, the signal from the pick-up coil(s) is used for measuring external magnetic field values less than about 0.5 mT. In a further embodiment, the signal from the pick-up coil is used for measuring the external magnetic field values in the range of about 0.1 nT to about 0.5 mT. In a further embodiment, the magnetoresistance of the core(s) is used for measuring external magnetic fields greater than 0.5 mT. Preferably, the magnetoresistance of the core(s) is used for measuring external magnetic field values in the range of about 0.5 mT to about 7 T. In a further embodiment, the magnetoresistance of the core(s) is used for measuring external magnetic fields up to at least about 12 T. In a further embodiment, the magnetoresistance of the core(s) is used for measuring external magnetic fields up to at least about 30 T.

In an embodiment, the magnetometer comprises a fluxgate arrangement, wherein the core(s), at least two excitation coils and the pick-up coil(s) are components of the fluxgate arrangement.

In an embodiment, the alternating current that drives the excitation coil(s) to induce fields that can drive at least one core into saturation during part of the AC cycle has a peak current of about 1 μA to about 5 A and is at a frequency greater than about 10 kHz. In a further embodiment, the frequency of the alternating current is about 10 kHz to about 100 kHz. In a further embodiment, the frequency of the alternating current is greater than about 100 kHz. In an embodiment, the magnetometer comprises two excitation coils near or around the core or a respective one of the cores, and the excitation coils are configured to induce two synchronous parallel fields in regions of the core surrounded by or near the excitation coils. In an alternative embodiment, the magnetometer comprises two excitation coils near or around one of the cores, and the excitation coils are configured to induce two synchronous anti-parallel alternating fields in the core. In a further embodiment, the excitation coils are configured to induce two synchronous anti-parallel alternating fields in regions of the core surrounded by or near the excitation coils.

In an embodiment, the magnetometer comprises a pair of electrodes electrically coupled to the core or a respective one of the cores for measuring magnetoresistance of the core. Preferably, the electrodes are electrically connected to a Wheatstone bridge arrangement for generating a voltage difference that is indicative of the external magnetic field. Preferably, the magnetometer comprises more than one pair of electrodes electrically coupled to the core(s) to measure the magnetic field gradient of the external magnetic field and/or to measure the magnetoresistance of the core(s) to improve the signal-to-noise ratio of the magnetoresistance measurements.

In an embodiment, a wire for carrying a current is placed proximate to the core(s), and the current carried by the wire is determined by measuring the external magnetic field resulting from the current flowing through the wire. Preferably, the wire for carrying the current is wound around or placed through the core(s).

In an embodiment, the core(s) is/are cylindrical. In one embodiment, the magnetometer comprises two cores, four excitation coils, and a pick-up coil, and two excitation coils near or around opposite ends of a respective one of the cores, and the pick-up coil is near or around both cores. In one embodiment, windings of the excitation coils for the same core are in the same direction and in an opposite direction for different cores. Alternatively, a winding of one of the excitation coils is in an opposite direction to a winding of the other excitation coil for the same core.

In an embodiment, at least one core is a toroidal-shaped core. Preferably, the excitation coils are positioned around and through the toriodal-shaped core, and the pick-up coil is positioned over the toriodal-shaped core.

In an embodiment, at least one core is a circular-, elliptical- or rectangular-shaped core.

In an embodiment, at least one core is a substantially cross-shaped core (or cruciform shaped) and the magnetometer comprises four excitation coils, each excitation coil around or near or adjacent to a respective arm of the cross-shaped core.

In an embodiment, the core is a cylindrical-shaped core, the excitation coils are near or around different sections of the core, and the pick-up coil is near or around the cores. In an embodiment, the magnetometer comprises a controller configured to:
receive magnetoresistance measurements from the core(s);
receive measurements of the induced signal from the pick-up coil(s); and
determine the external magnetic field based on the magnetoresistance measurements and/or measurements of the induced signal from the pick-up coil(s).

In an embodiment, the controller is configured to determine the external magnetic field based on at least the magnetoresistive measurements where the external magnetic field is sufficient to saturate at least one of the cores. In a further embodiment, the controller is configured to determine the external magnetic field based on at least measurements of the induced signal from the pick-up coil(s) where the external magnetic field falls below a threshold. Preferably, the threshold is less than about the saturation field of the core(s), which is the magnetic field which saturates the core(s). In a further embodiment, the controller uses the magnetoresistive measurements when the sensitivity of measurements of the induced signal in the pick-up coil falls below a pre-determined threshold. In preferred embodiments, this threshold is chosen lower than the saturation field of the core.

In an embodiment, the controller comprises a multiplexor circuit arrangement for outputting one of the external magnetic field measurements based on the magnetoresistance and the induced signal based on the sensitivity of the induced signal measurements in the pick-up coil(s).

According to a second aspect, the present invention provides a method of measuring an external magnetic field using a magnetometer of the first aspect of the invention, the method comprising: (a) using the signal from the pick-up coil(s) for measuring external magnetic fields below a defined magnetic field threshold; and (b) using the magnetoresistance of the core(s) for measuring external magnetic fields above the defined magnetic field threshold.

In an embodiment, the defined magnetic field threshold is the saturation field of the pick-up coil, which is the field at which the signal from the pick-up coil begins to show a saturated response. Preferably, step (a) comprises using the signal from the pick-up coil for measuring external magnetic field values less than the saturation field of the signal from the pick-up coil while the pick-up coil is on its linear and non-linear regime up to the saturation field, while step (b) comprises using the magnetoresistance of the core(s) for measuring external magnetic field values greater than the saturation field of the signal from the pick-up coil. The signal from the pick-up coil may have a substantially linear and/or a non-linear response up to the saturation field. Preferably, the defined magnetic field threshold is about 1.5 mT.

In an embodiment, the defined magnetic field threshold is the non-linear field, which is the field at which the signal from the pick-up coil switches from a linear response to a non-linear response. Preferably, step (a) comprises using the signal from the pick-up coil for measuring external magnetic field values less than the non-linear field of the signal from the pick-up coil while the pick-up coil is on its linear regime, while step (b) comprises using the magnetoresistance of the core(s) for measuring external magnetic field values greater than the non-linear field of the signal from the pick-up coil. Preferably, the signal from the pick-up coil is linear with less than 1% non-linearity up to about 0.5 mT, and the defined magnetic field threshold is about 0.5 mT.

In an embodiment, step (a) comprises using the signal from the pick-up coil(s) for measuring external magnetic field values down to about 0.1 nT.

In an embodiment, step (b) comprises using the magnetoresistance of the core(s) for measuring external magnetic field values up to at least about 7 T. Preferably, step (b) comprises using the magnetoresistance of the core(s) for measuring external magnetic field values up to at least about 12 T. Preferably, step (b) comprises using the magnetoresistance of the core(s) for measuring external magnetic field values up to at least about 30 T.

In a further embodiment, the method comprises driving the excitation coil(s) with an alternating current to induce fields that saturate the core during part of the AC cycle having a peak current of about 1 pA to about 5 A and at a frequency greater than about 10 kHz. In a further embodiment, the frequency of the alternating current is about 10 kHz to about 100 kHz. In a further embodiment, the frequency of the alternating current is greater than about 100 kHz. In an embodiment, the magnetometer comprises two excitation coils, and the method further comprises using the excitation coils to induce two synchronous anti-parallel alternating fields in regions of the core or cores surrounded by or near each excitation coil. In an alternative embodiment, the magnetometer comprises two excitation coils and the method further comprises using the excitation coils to induce two synchronous parallel alternating fields in regions of the core(s) surrounded by or near each excitation coil.

In an embodiment, the method further comprises placing a wire for carrying a current proximate to the core(s) for measuring the external magnetic field resulting from the current flowing through the wire. Preferably, the method comprises winding the wire around or placing the wire through the core(s).

A third aspect of the invention provides a method of assembling a magnetometer, the method comprising the steps of:

(a) electrically coupling electrodes to one of at least one magnetoresistive core;
(b) winding at least one excitation coil near or around at least part of the core(s);
(c) winding at least one pick-up coil near or around the excitation coil(s) and the core(s).

In an embodiment, the core(s) comprise(s) a high permeability superparamagnetic magnetoresistive material comprising nanoparticles, and the material exhibits electron spin polarisation for negative magnetoresistances, which arises from spin tunneling between nanoparticles over a range of operating temperatures. Preferably, the high permeability superparamagnetic magnetoresistive material comprises nanoparticles chosen from the group consisting of iron, nickel, cobalt, their alloys and oxides, and mixtures thereof showing ferromagnetic behaviour at room temperature. Preferably, the high permeability superparamagnetic magnetoresistive material comprises nanoparticles of a ferromagnetic ferrite. Preferably, the ferromagnetic ferrite is chosen from the group consisting of ZnFe₂O₄, BaFe₁₂O₉, and Ni_{0.5}Zn_{0.5}Fe₂O₄.

In an embodiment, the core(s) comprise(s) a blocking temperature substantially below an operating temperature range and a Curie temperature substantially above the operating temperature range. Preferably, the blocking temperature of the core(s) is below about 200 K and the Curie temperature of the core(s) is above about 313 K.

In an embodiment, a relative permeability of the core(s) is greater than 1. Preferably, the relative permeability of the core(s) is greater than 50. Preferably, the relative permeability of the core(s) is greater than 1000.

In an embodiment, the core(s) comprise(s) a pressed nanoparticle powder. Preferably, the pressed nanoparticle powder comprises core/shell nanoparticles. Preferably, the pressed nanoparticle powder comprises iron (II, III) oxide nanoparticles.

In an embodiment, the core(s) comprise(s) a magnetoresistive film containing nanoparticles. Preferably, the method comprises synthesising or embedding the nanoparticles on or in a surface of a substrate of the film. Preferably, the film comprises silicon dioxide and iron nanoparticles. Preferably, the magnetoresistive film containing nanoparticles is a thin film. Preferably, where the core is the thin film, the excitation coil(s) and/or the pick-up coil(s) is/are near the thin film. Alternatively, the magnetoresistive film containing nanoparticles may be a thick film. Preferably, where the core is the thick film, the excitation coil(s) and/or the pick-up coil(s) is/are near or around the thick film.

In an embodiment, the electrodes are configured to measure a magnetoresistance of the core(s), the magnetoresistance and a signal carried by the pick-up coil(s) being measurable in response to an external magnetic field.

In an embodiment, the magnetometer comprises two or more excitation coils, and the excitation coils are configured to be driven by an alternating current to partially saturate a magnetisation of the core(s) during part of the AC cycle. In a further embodiment, the coils are configured to induce anti-parallel or parallel alternating fields in the core(s). Preferably, the magnetometer comprises two excitation coils, and the excitation coils are configured to induce two synchronous anti-parallel alternating fields in the core(s). Preferably, step (a) comprises electrically connecting the electrodes to a Wheatstone bridge arrangement, the Wheatstone bridge arrangement being configured to generate a voltage difference that is indicative of external magnetic field.

In an embodiment, step (a) comprises electrically coupling a plurality of pairs of electrodes to the core(s), the pairs being arranged to measure a magnetic field gradient of the external magnetic field and/or each or at least one pair being configured to measure the magnetoresistance of the core(s).

In an embodiment, at least one core is a toroidal-shaped core. Preferably, the excitation coils are wound around and through the toriodal-shaped core.

In an alternative embodiment, at least one core is a circular-, elliptical- or rectangular-shaped core.

In an embodiment, at least one core is a substantially cross-shaped core (or cruciform-shaped core) and the method comprises winding at least one excitation coil around each arm of the cross-shaped core.

In an embodiment, at least one core is a pellet core, and step (a) comprises electrically coupling the electrodes to an end of the pellet core. In an alternative embodiment, at least one core is a pellet core, and step (a) comprises electrically coupling the electrodes along a length of the pellet core. In an alternative embodiment, at least one core is a pellet core, and step (a) comprises electrically coupling the electrodes along a cross sectional area of the pellet core. In an alternative embodiment, at least one core is a pellet core, and step (a) comprises electrically coupling the electrodes to opposite ends of the pellet core. In a further embodiment, at least one core is a pellet core, and the method further comprises moulding the pellet core around the electrodes.

In an embodiment, the method further comprises stacking a plurality of magnetoresistive cores to form a column of cores. Preferably, step (a) comprises electrically coupling electrodes to the core substantially in the middle of the column of cores. Alternatively, step (a) comprises electrically coupling electrodes to the core at an end of the column of cores. Alternatively, step (a) comprises electrically coupling electrodes to cores at opposite ends of the column of cores.

In an embodiment, the method further comprises electrically coupling the electrodes and the pick-up coil(s) to a controller, wherein the controller is configured to: receive magnetoresistance measurements from the core(s); receive measurements of the induced signal from the pick-up coil(s); and determine the external magnetic field based on the magnetoresistance measurements and/or measurements of the induced signal from the pick-up coil(s).

In an embodiment, the magnetometer comprises three cores and six excitation coils for magnetic field measurements in three axes, and the method further comprises locating a respective pair of excitation coils around or near one of the respective cores. In an alternative embodiment, the magnetometer comprises three cores and three excitation coils for magnetic field measurements in three axes, and the method further comprises locating a respective excitation coil around or near one of the respective cores. In a further embodiment, the cores are positioned orthogonally to each other core, and magnetic field measurements from the core in an axis represent the external magnetic field in that axis. In a further embodiment, the magnetometer comprises two toroidal-shaped cores.

In an alternative embodiment, the magnetometer comprises six cores and twelve excitation coils for magnetic field measurements in three axes, and the method comprises locating two excitation coils around or near each of the cores. In an alternative embodiment, the magnetometer comprises six cores and six excitation coils. In a further embodiment, three pairs of cores are positioned orthogonally to each other pair, and magnetic field measurements from two respective cores in an axis represent the external magnetic field in that axis.

In a further embodiment, the magnetometer comprises a plurality of pick-up coils, and the method comprises positioning each pick-up coil near or around different portions of the core and the excitation coil(s) or around pairs of cores. Preferably, the magnetometer comprises a first pick-up coil positioned above the core and excitation coil(s) or around a pair of excitation coils.

A fourth aspect of the invention provides a method for assembling a magnetometer comprising the steps of:
(a) depositing different metallic layers in the shape of planar coils separated by insulating layers onto one or more substrates containing superparamagnetic nanoparticles;
(b) electrically coupling electrodes to the substrate(s) containing superparamagnetic nanoparticles.

In an embodiment, the superparamagnetic nanoparticles form a magnetoresistive material that exhibits electron spin polarisation for negative magnetoresistances, which arises from spin tunneling between nanoparticles over a range of operating temperatures.

In an embodiment, the superparamagnetic nanoparticles are chosen from the group consisting of iron, nickel, cobalt, their alloys and oxides, and mixtures thereof showing ferromagnetic behaviour at room temperature. In a further embodiment, the superparamagnetic nanoparticles comprise a ferromagnetic ferrite. Preferably, the ferromagnetic ferrite is chosen from the group consisting of ZnFe₂O₄, BaFe₁₂O₉, and Ni_{0.5}Zn_{0.5}Fe₂O₄.

In an embodiment, the superparamagnetic nanoparticles form a material comprising a blocking temperature substantially below an operating temperature range and a Curie temperature substantially above the operating temperature range. Preferably, the blocking temperature of the core(s) is below about 200 K and the Curie temperature of the core(s) is above about 313 K.

In an embodiment, the superparamagnetic nanoparticles form a material that has a relative permeability greater than 1. Preferably, the relative permeability is greater than 50. Preferably, the relative permeability is greater than 1000.

In an embodiment, the superparamagnetic nanoparticles comprise core/shell nanoparticles. In a further embodiment, the superparamagnetic nanoparticles comprise iron (II, III) oxide nanoparticles.

In an embodiment, the substrates containing superparamagnetic nanoparticles are a film. Preferably, the film comprises silicon dioxide and iron nanoparticles. Preferably, the substrates containing superparamagnetic particles are a thin film. Preferably, where the substrates containing superparamagnetic nanoparticles are a thin film, the planar coils are near the thin film. Alternatively, the substrates containing superparamagnetic particles are a thick film. Preferably, where the substrates containing superparamagnetic nanoparticles are a thick film, the planar coils are near or around the thick film.

In an embodiment, the method further comprises synthesising or embedding the superparamagnetic nanoparticles on or in a surface of the substrate. In an embodiment, the electrodes are configured to measure a magnetoresistance and one of the planar coils is a pick-up coil, the magnetoresistance and a signal carried by the pick-up coil being measurable in response to external magnetic fields.

In an embodiment, two planar coils are excitation coils and are configured to induce magnetic fields in the substrates containing superparamagnetic nanoparticles. In an embodiment, the magnetometer comprises two excitation coils, and the method further comprises using the excitation coils to induce two synchronous anti-parallel alternating fields in regions of the core or cores near each excitation coil. In an alternative embodiment, the magnetometer comprises two excitation coils and the method further comprises using the excitation coils to induce two synchronous parallel alternating fields in regions of the core(s) near each excitation coil.

In an embodiment, step (a) comprises electrically connecting the electrodes to a Wheatstone bridge arrangement, and the Wheatstone bridge being configured to generate a voltage difference that is indicative of external magnetic fields.

In an embodiment, step (a) comprises electrically coupling a plurality of pairs of electrodes to the core(s), the pairs being arranged to measure a magnetic field gradient of the external magnetic field and/or each or at least one pair being configured to measure the magnetoresistance of the substrates containing superparamagnetic nanoparticles.

In an embodiment, the method further comprises electrically coupling the electrodes and at least one planar coil to a controller, wherein the controller is configured to: receive magnetoresistance measurements from the core(s); receive measurements of a signal from at least one planar coil, the signal being induced in the presence of external magnetic fields; and determine the external magnetic fields based on the magnetoresistance measurements and/or measurements of the induced signal from the planar coil.

In an embodiment, step (a) comprises locating planar excitation coils and planar pick-up coils on different substrates, and assembling the planar excitation coils and planar pick-up coils with the substrates containing superparamagnetic nanoparticles.

In an embodiment, planar excitation coils and pick-up coils are located on different substrates and are assembled and stacked with the substrate containing superparamagnetic nanoparticles.

In an embodiment, the core is a circular-, elliptical-, rectangular-shaped core. In a further embodiment, the core is configured to measure the electrical current carried by a wire by placing the wire near the core. In an alternative embodiment, the core is substantially cross-shaped (or cruciform-shaped). In the embodiment where the core is substantially cross-shaped, the magnetometer comprises four excitation coils, each excitation coil around or near or adjacent a respective arm of the cross-shaped core to enable two components of the magnetic field to be measured. In a further embodiment, the magnetometer comprises three cores and six excitation coils for magnetic field measurements in three axes, wherein a respective pair of excitation coils are near one of the respective cores.

In an embodiment, the magnetometer comprises a plurality of pick-up coils. In a further embodiment, the magnetometer comprises two pick-up coils, wherein the pick-up coils are each near or around different portions of the core and the excitation coil(s). In a further embodiment, the magnetometer comprises one pick-up coil positioned above the core and excitation coil(s) and the other pick-up coil is positioned below the core and excitation coil(s).

In an embodiment, the magnetometer is suitable for use as a magnetic field sensing device and/or current sensing device.

A fifth aspect of the invention provides a magnetometer when assembled by the method of the third or fourth aspects of the invention.

Where specific integers are mentioned herein which have known equivalents in the art to which this invention relates, such known equivalents are deemed to be incorporated herein as if individually set forth.

In addition, where features or aspects of the invention are described in terms of Markush groups, those persons skilled in the art will appreciate that the invention is also thereby described in terms of any individual member or subgroup of members of the Markush group.

As used herein ‘(s)’ following a noun means the plural and/or singular forms of the noun.

As used herein the term ‘and/or’ means ‘and’ or ‘or’ or both.

The term ‘comprising’ as used in this specification means ‘consisting at least in part of’. When interpreting each statement in this specification that includes the term ‘comprising’, features other than that or those prefaced by the term may also be present. Related terms such as ‘comprise’ and ‘comprises’ are to be interpreted in the same manner.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

In this specification where reference has been made to patent specifications, other external documents, or other sources of information, this is generally for the purpose of providing a context for discussing the features of the invention. Unless specifically stated otherwise, reference to such external documents or such sources of information is not to be construed as an admission that such documents or such sources of information, in any jurisdiction, are prior art or form part of the common general knowledge in the art.

Although the present invention is broadly as defined above, those persons skilled in the art will appreciate that the invention is not limited thereto and that the invention also includes embodiments of which the following description gives examples.

### BRIEF DESCRIPTION OF THE FIGURES

Embodiments of the invention will now be described, by way of non-limiting example, with reference to the Figures in which:

FIG. 1 shows a first embodiment of the magnetometer of the present invention;

FIG. 2 shows a second embodiment of the magnetometer of the present invention;

FIG. 3A shows a partial perspective view of a core and excitation coils for an embodiment of the magnetometer of the present invention;

FIG. 3B shows a perspective view of the pick-up coil for an embodiment of the magnetometer;

FIG. 3C shows a partial perspective view of the core and excitation coils of FIG. 3B and the pick-up coil of FIG. 3B when assembled for an embodiment of the magnetometer;

FIG. 4A shows a perspective view of excitation coils for a third embodiment of the magnetometer of the present invention;

FIG. 4B shows a perspective view of a pick-up coil for an embodiment of the magnetometer;

FIG. 4C shows a perspective view of the excitation coils of FIG. 4A with the pick-up coil of FIG. 4B when assembled to a core for an embodiment of the magnetometer;

FIGS. 5A-E show different configurations of electrodes on the core;

FIGS. 6A and 5B show embodiments of the magnetometer of the present invention with different electrode configurations;

FIG. 7 shows a fourth embodiment of the magnetometer of the present invention;

FIG. 8 shows another embodiment of the magnetometer of the present invention suitable for current measurements;

FIG. 9 is a flowchart illustrating the operation of a magnetometer according to one embodiment of the present invention;

FIG. 10 shows the evolution of the magnetisation against an applied magnetic field at room temperature for a typical nanopowder core;

FIG. 11 shows the magnetoresistance from a Fe implanted thin film comprising near surface Fe nanoparticles with an electrode gap of 1 mm;

FIG. 12A shows the output voltage of a pick-up coil of a magnetometer of the present invention in response to a range of applied external magnetic fields;

FIG. 12B shows the output voltage of a magnetoresistive core of a magnetometer of the present invention in response to a range of applied external magnetic fields; and

FIG. 13 shows the output of a magnetometer of the present invention simulated using the data shown in FIGS. 12A and 12B.

### DETAILED DESCRIPTION OF THE INVENTION

The embodiments of the magnetometer described below are suitable for magnetic field measurements over a wide dynamic magnetic field range. Embodiments of the magnetometer described below have applications as a magnetic field sensor and/or as a current sensor, for example.

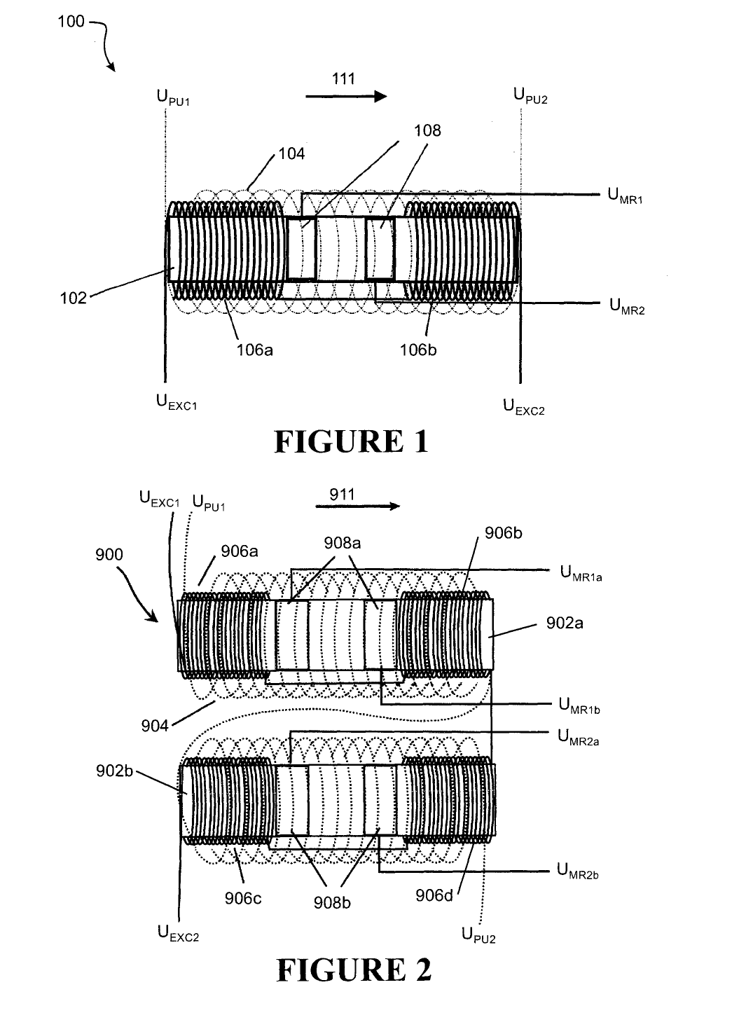

An embodiment of the magnetometer 100 of the present invention is illustrated in FIG. 1. The magnetometer 100 comprises a core 102, a pick-up coil 104, excitation coils 106a,b, and a pair of electrodes 108. In some embodiments, the magnetometer may comprise more than one core, more than one pick-up coil, or one or more than two excitation coils.

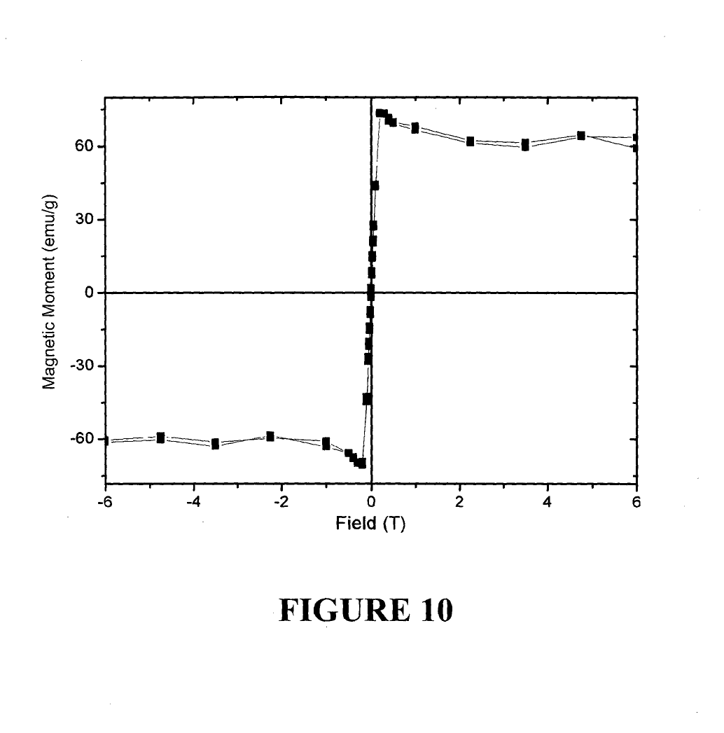

The core 102 has a magnetoresistive property that is measurable in response to an applied external magnetic field 111. The term ‘magnetoresistive property’ refers to the property of a material having a resistance that is a function of the applied external magnetic field, R(B). FIG. 10 shows an example of the resistance response of a magnetoresistive material to an applied magnetic field. To determine the resistance of a magnetoresistive material, a current is applied through the magnetoresistive material so that a voltage can be measured across the material. Thereby, the resistance of the magnetoresistive material can be determined. As used herein, the terms ‘magnetoresistive property’, ‘magnetoresistance’ and ‘resistance’ refer to the resistance of the magnetoresistive core. The magnetoresistance measurements are generally indicative of external magnetic field values in the range of about 1 mT to tens of Teslas depending on the material from which the core is formed. The properties and construction of the magnetoresistive core 102 will be described in further detail below.

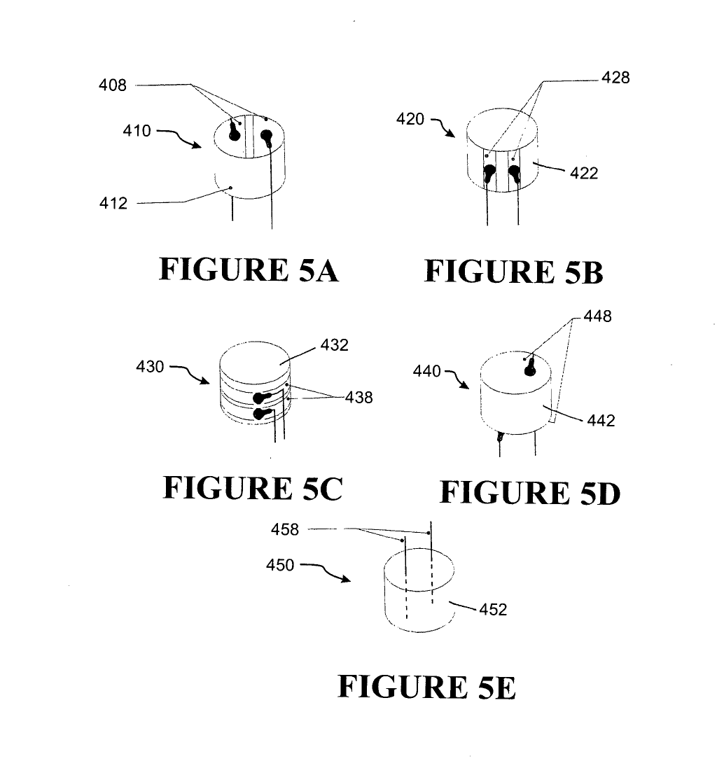

The electrodes 108 are used to determine the resistance of the core 102. The pair of electrodes 108 is electrically coupled to the core 102 to determine the magnetoresistance of the core across points U_{MR1} and U_{MR2}. The separation between the electrodes may be selected to minimise the resistance and hence the thermal voltage noise. The magnetoresistance measurements are also affected by the location of the electrodes 108 on the core 102. The operation of the electrodes 108 on the core does not affect or is not affected by the operation of the excitation coils 106a,b. While FIG. 1 shows that the magnetoresistance measurements are taken at the centre of the core 102, additional or alternative magnetoresistance measurements may be taken elsewhere on the core 102 according to other embodiments of the magnetometer. In one embodiment, the electrodes 108 may be positioned in the middle of the core to improve the sensitivity of the measurements. That embodiment is shown by way of example in FIG. 5A. In that embodiment, parts of the core over and below the electrodes will act as a magnetic flux concentrator.

In the embodiment shown in FIG. 1, the excitation coils 106a,b around the core 102 are configured to saturate the magnetisation of the core in the absence of an external magnetic field. The excitation coils 106a,b are wound around opposite ends of the core 102. In other embodiments, the excitation coils may be placed on or near the core instead of around the core.

The excitation coils 106a,b are formed from a single wire. In the embodiment shown in FIG. 1, the excitation coils 106a,b are driven by a single AC current source (not shown). However, in other embodiments, an excitation coil at an end of the core may be independent of the excitation coil at an opposite end of the core, and each excitation coil is driven by an independent AC current source. Passing an excitation signal through the excitation coils 106a,b induces magnetic fields in the core 102. The excitation coils 106a,b are driven with an alternating current to induce magnetic fields that can drive the magnetisation of the core into saturation during part of an AC cycle. The alternating current has a peak current of about 1 pA to about 5 A and frequency greater than about 10 kHz. In other embodiments, the current has a frequency of about 10 kHz to about 100 kHz. In other embodiments, the current has a frequency greater than about 100 kHz. The frequency of the current is limited by the inductance of the coils.

The excitation signal from the AC current source in the excitation coils 106a,b is high enough to drive the core 102 from one magnetisation saturation (positive saturation) to the other (negative saturation), and vice versa during part of an AC cycle.

In the presence of an external magnetic field 111 with a component on the principal axis of the core 102, the external magnetic field 111 will act as a positive offset in the magnetic field at one half of the core 102 and a negative offset at the other half of the core 102. Consequently, in the presence of an external magnetic field 111, the magnetisation of the core 102 is periodically unbalanced. The resulting magnetisation of the core 102 in the presence of an external magnetic field 111 is non-zero, oscillating at twice the frequency of the excitation signals.

In one embodiment, the winding of one excitation coil 106a is clockwise relative to a first end of the core around the first half of the core 102 and the winding of the other excitation coil 106b is anticlockwise relative to the first end of the core around the second half of the core 102. If the current passing through the excitation coils 106a,b is large enough, and the permeability of the core 102 is low enough then the region of the core 102 surrounded by the excitation coils 106a,b will be partially saturated during part of each AC cycle and near each end of the core 102. In the absence of an external magnetic field, the magnetic fields induced by the two excitation coils 106a,b in the core 102 oppose each other with a substantially equal magnitude, and resulting in a zero net magnetic field in the pickup coil 104 when there is no external applied magnetic field. In this arrangement, a current with a frequency of twice that of the excitation frequency will be induced in the pick-up coil 104 when an external magnetic field 111 is applied to the magnetometer 100.

In another embodiment, the windings of the excitation coils 106a,b are in the same direction relative to one end of the core around opposite halves of the core 102. If the current passing through the excitation coils 106a,b is large enough then the core 102 will be partially saturated during part of each AC cycle. In the absence of an external magnetic field, a signal is induced in the pick-up coil 104 at twice the frequency of the current passing through the excitation coils 106a,b. Applying an external magnetic field 111 to the magnetometer 100 will lead to an imbalance in the core saturation and change the time interval between the negative and positive signals induced in the pick-up coil 104. This change in the time interval can be used to determine the external magnetic field 111. In another embodiment, the current passing through the excitation coils 106a,b is modified so that the signal in the pick-up coil 104 is a series of positive and negative pulses. The application of an external magnetic field 111 to the magnetometer 100 leads to a change in the peak voltages of different pulses, which can be used to measure the external magnetic field 111.

In some embodiments, the magnetometer may comprise more than one pair of excitation coils. For the embodiment of the magnetometer described above, wherein the excitation coils are configured to induce a substantially zero net magnetic field in the pickup coil, the magnetometer may for example comprise an even number of excitation coils so that the total time-varying magnetic field in the pick-up coil is zero when there is no external applied magnetic field.

The pick-up coil 104 is positioned or wound over the excitation coils 106a,b and the magnetoresistive core 102. The pick-up coil 104 is positioned or wound in such a way that the pick-up coil is able to measure the total change in the magnetic fields in the excitation coils 106a,b and the core 102.

The pair of electrodes 108 is electrically coupled to the core 102. The pick-up coil 104 is configured to carry a signal induced at least in the presence of the external magnetic field 111.

When an external magnetic field 111 is applied, a signal is induced in the pick-up coil depending on the configuration of the excitation coils during part of the AC cycle. The change in the magnetic field within the pick-up coil 104 induces a voltage signal in the pick-up coil 104 at twice the excitation frequency. The induced signal is measurable across points U_{PU1} and U_{PU2} in response to the external magnetic field. The induced signal measurements are generally indicative for lower external magnetic field values in the range of about 0.1 nT to about 0.05 T.

In some embodiments, the magnetometer may comprise more than one pick-up coil around or near the core(s). According to different configurations of those embodiments, the pick-up coils may be formed of a single wire, or may each be formed of a separate wire.

An embodiment of the magnetometer 900 with two cores of the present invention is illustrated in FIG. 2. The magnetometer 900 comprises two cores 902a,b, a pick-up coil 904, excitation coils 906a-d, and two pairs of electrodes 908a,b.

Each of the cores 902a,b has a magnetoresistive property that is measurable in response to an applied external magnetic field 911

The electrodes 908a,b are used to determine the resistance of the cores 902a,b. Each pair of electrodes 908a,b is electrically coupled to a respective core 902a,b to determine the magnetoresistance of the core across points U_{MR1a} and U_{MR1b} or U_{MR2a} and U_{MR2b}. The separation between the electrodes 908a,b on a respective core 902a,b may be selected to minimise the resistance and hence the thermal voltage noise. The magnetoresistance measurements are also affected by the location of the electrodes 908a,b on the respective core 902a,b. The operation of the electrodes 908a,b does not affect or is not affected by the operation of the excitation coils 906a-d. While FIG. 2 shows that the magnetoresistance measurements are taken at the centre of the cores 902a,b, additional or alternative magnetoresistance measurements may be taken elsewhere on the cores 902a,b according to other embodiments of the magnetometer. In one embodiment, the electrodes 908a,b may be positioned in the middle of the respective core 902a,b to improve the sensitivity of the measurements. That embodiment is shown by way of example in FIG. 5a. In that embodiment, parts of the core over and below the electrodes will act as a magnetic flux concentrator.

In the embodiment shown in FIG. 2, the excitation coils 906a-d around the cores 902a,b are configured to saturate the magnetisation of the cores 902a,b, in the absence of an external magnetic field 911. Two excitation coils 906a,b are positioned or wound around opposite ends of one of the cores 902a, while the other two excitation coils are positioned or wound around opposite ends of the other core 902b. In other embodiments, the excitation coils may be placed on or near the respective core instead of around the respective core.

The excitation coils 906a-d are formed from a single wire. According to other embodiments, the excitation coils 906a-d are each formed from a separate wire. According to still other embodiments, the excitation coils 906a,b for one of the cores 902a may be formed from a single wire that is separate from the wire used to form the other excitation coils 906c,d for the other core 902b. The winding of excitation coils 906a-d around a respective core 902a,b are in the same direction. The winding of the excitation coils 906a,b around one core 902a is in an opposite direction to the winding of the excitation coils 906c,d around the other core 902b. In the embodiment shown in FIG. 2, the excitation coils 906a-d are driven by a single AC current source (not shown). However, in other embodiments, each of the excitation coils is driven by independent AC current sources. Passing an excitation signal through the excitation coils 106a,b induces magnetic fields in the cores 902a,b. The excitation coils 906a-d are driven with an alternating current to induce magnetic fields that can drive the cores 902a,b into saturation during part of an AC cycle. The alternating current has a peak current of about 1 pA to 5 A and a frequency of greater than about 10 kHz. In some embodiments, the current has a frequency of about 10 kHz to about 100 kHz. In other embodiments, the current has a frequency greater than about 100 kHz. The frequency of the current is limited by the inductance of the coils.

The excitation signal from the AC current source in the excitation coils 906a-d is high enough to drive the respective core from one magnetisation saturation (positive saturation) to the other (negative saturation), and vice versa during part of the AC cycle. In the absence of an external magnetic field, the magnetic field induced by the excitation coils 906a,b in one of the cores 902a is opposite to the magnetic field induced by the excitation coils 906c,d in the other core 902b. In the absence of an external magnetic field 911, the sum of the magnetic fields in the first and second core 902a,b is substantially zero. In the presence of an external field with a component on the principal axis of the cores 902a,b, the external field 911 will act as a positive offset in the magnetic field in one core and a negative offset for the other core. The sum of the magnetic fields from each core 902a,b in the presence of an external magnetic field is non-zero, oscillating at twice the frequency of the excitation signals.

In some embodiments, the magnetometer may comprise more than two pairs of excitation coils. The magnetometer comprises an even number of excitation coils so that the total magnetic field from a pair of cores is substantially zero in the absence of an external magnetic field.

The pick-up coil 904 is wound over the excitation coils 906a-d and the magnetoresistive cores 902a,b. The pick-up coil 904 is wound in such a way to measure the total change in the magnetic fields in the excitation coils 906a-d or in the cores 102a,b. The pairs of electrodes 908a,b are electrically coupled to the respective cores 102a,b. The pick-up coil 904 is configured to carry a signal induced at least in the presence of the external magnetic field. When an external magnetic field 911 is applied to the magnetometer 900, the net magnetic field becomes non-zero during part of the AC cycle. The change in the magnetic field within the pick-up coil 904 induces a voltage signal in the pick-up coil 904 at twice the excitation frequency. The induced signal measurements are generally indicative for lower external magnetic field values in the range of about 0.1 nT to about 0.05 T.

As shown in FIG. 2, the pick-up coil 904 around the two cores 902a,b is formed from a single wire. In some embodiments, the magnetometer may comprise more than one pick-up coil around or near each of the cores, each pick-up coil being formed from a separate wire.

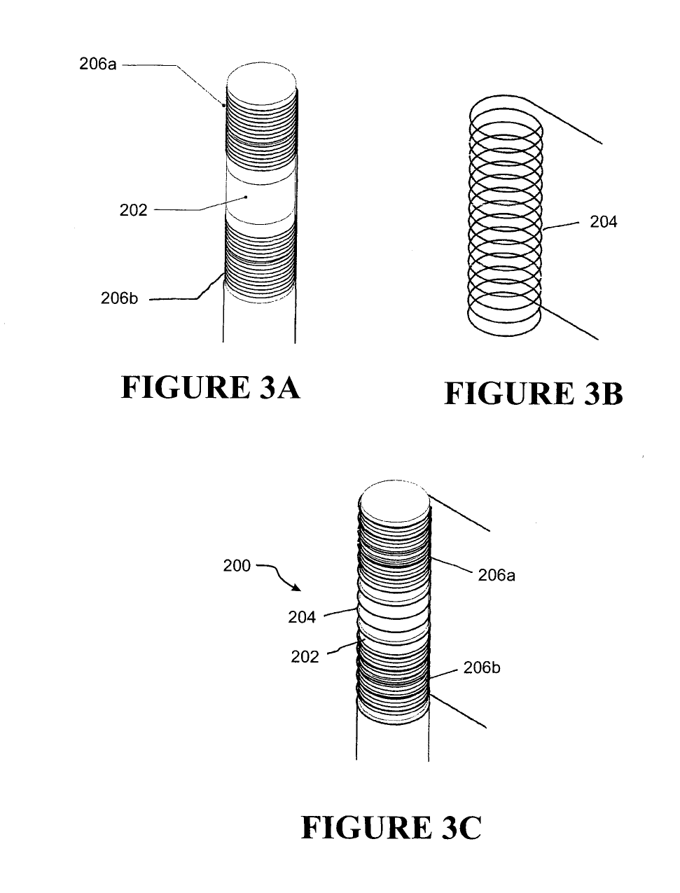

Referring to FIGS. 3A-C, the cores with the excitation coils can be fabricated by positioning or winding excitation coils 206a and 206b around the superparamagnetic core 202 that also includes electrodes (not shown) for magnetoresistance sensing. According to other embodiments, the excitation coils 206a and 206b may be replaced by a single excitation coil. As shown in FIG. 3A, the core 202 is formed of a stack of cores. The pick-up coil 204, shown in FIG. 3B, is positioned or wound around the excitation coils 206a and 206b and the core 202 to form the magnetometer components 200 shown in FIG. 3C. The magnetometer may comprise one or more magnetometer components shown in FIG. 3C. In an example configuration, the magnetometer comprises one core, where one of the excitation coils 206a is wound clockwise and the other excitation coil 206b is wound anticlockwise around the core 202. In this configuration, the core 202 comprises a low permeability.

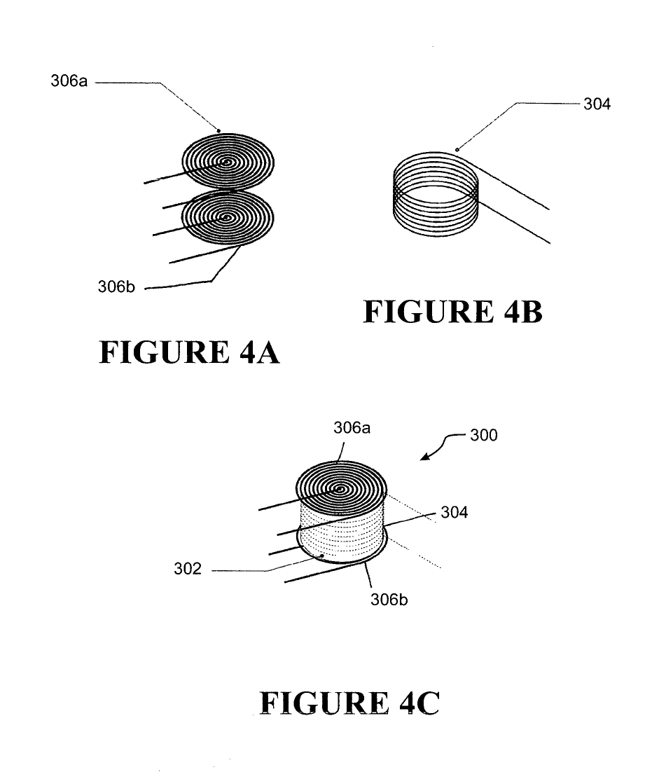

An alternative configuration of the magnetometer components 300 is shown in FIG. 4C. In that configuration, the magnetometer components 300 comprise planar excitation coils 306a and 306b (as shown in FIG. 4A), also known as pancake coils, placed at either end of the core 302. The pick-up coil 304 (as shown in FIG. 4B) is positioned or wound around the cylindrical core 302. According to other embodiments of this configuration, the magnetometer may comprise two cores with a pick-up coil around each core, and the pick-up coils are configured to measure the sum of the changes in the magnetic fields in both cores.

Referring to FIGS. 1 and 2, in one implementation, an AC excitation signal with a frequency f is applied across the points U_{EXC1} and U_{EXC2} of the excitation coils 106a,b or 906a-d. The excitation coils are wound so that the magnetic field in the pick-up coil is substantially zero in the absence of external magnetic fields. High frequencies are used to reduce the signal-to-noise ratio, which is proportional to the frequency. Frequencies higher than 100 kHz would be useful for this reason. The excitation signal can be applied at all time or be switched off when not in use. A low pass filter can be applied to the magnetoresistance measurement circuit so that the excitation field signal can be filtered and not affect the magnetoresistance values. The external magnetic field when the measurements are based on the magnetoresistance of the core dominates the magnetic field induced by the excitation field. As the excitation coils may be wound differently at either end of the core 102 for the magnetometer shown in FIG. 1 or on each core 902a,b for the magnetometer shown in FIG. 2, the excitation magnetic fields from the two excitation coils are induced in the core(s) with opposite polarities. In the absence of an external magnetic field, the total magnetic field sensed by the pick-up coil is zero. When an external magnetic field is applied, the net magnetic field sensed by the pick-up coil is non-zero. The change in magnetic field induces a voltage signal with a frequency of 2f in the pick-up-coil. The pick-up signal is measured across the points U_{PU1} and U_{PU2}. By way of example, the direction of the external magnetic field is indicated by the arrow 111, 911.

With reference to the embodiment shown in FIG. 1, current flows between the two electrodes 108 through the core 102. The direction of the external magnetic field need not be in the same direction as the current through the core 102. The current can flow through the core 102 at all times and even during low external magnetic field measurements. Alternatively, the current through the core 102 could be switched off. The current flowing through the core 102 does not affect the measurements from the pick-up coil 104. The resistance of the core 102 varies depending on the strength of the external magnetic field. The resistance of the core 102 is measured across the points U_{MR1} and U_{MR2}.

With reference to the embodiment shown in FIG. 2, current flows between the two electrodes 908a through one of the cores 902a and/or through the two electrodes 908b in the other core 902b. The direction of the external magnetic field need not be in the same direction as the current through either core. The current can flow through the cores 902a,b at all times and even during low external magnetic field measurements. Alternatively, the current through the cores 902a,b could be switched off. The current flowing through the cores 902a,b does not affect the measurements from the pick-up coil 904. The resistance of the cores 902a,b varies depending on the strength of the external magnetic field. The resistance of the cores 902a,b is measured across the points U_{MR1a} and U_{MR1b} or U_{MR2a} and U_{MR2b}.

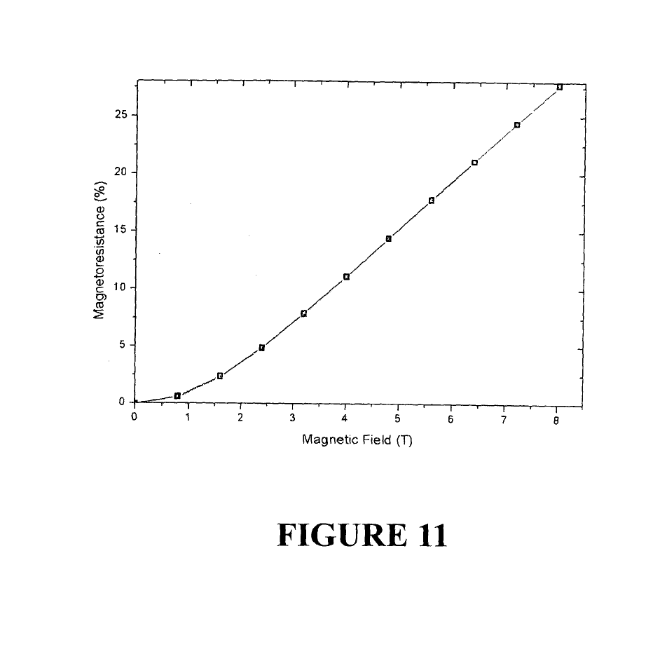

The external field can be measured using pick-up coil measurements for magnetic fields in the range of about 0 T up to saturation of the core(s). For these measurements, the response of the magnetometer has a linear region. The signal obtained from the pick-up coil of a magnetometer of the present invention after the lock-in amplifier is shown in FIG. 11A. The response of the pick-up coil is substantially linear for magnetic fields between 0 and 0.5 mT. This region in which the response of the pick-up coil signal is substantially linear is referred to herein as the linear region. At higher magnetic fields, the response of the pick-up coil signal becomes non-linear (in a non-linear region), and, after a saturation field, the signal from the pick-up coil has a saturated response. As used herein, the term ‘saturation field’ refers to a magnetic field at which the signal switches from a transient response (linear and/or non-linear response) to a saturation response. For the pick-up coil signal, the magnitude of the signal is at its maximum at the saturation field. At fields higher than the saturation field, the magnitude of the pick-up coil signal decreases non-linearly. According to an embodiment of the magnetometer of the present invention, the pick-up coil has a saturation field of about 1.5 mT, after which the response of the pick-up coil signal decreases. This limits the use of the pick-up signal for magnetic fields greater than the saturation field of the pick-up coil. With reference to FIG. 1, the external field can be measured using the core 102 measurements for magnetic fields greater than the saturation field of the pick-up coil 104. Depending on the type of application, higher saturation fields for the magnetoresistance are preferred, as this provides a better linearity for higher external magnetic field measurements. However, in other embodiments, the magnetoresistance can be non-linear for low magnetic fields and substantially linear for higher magnetic fields.

In a preferred embodiment, the pick-up coil signal saturates at an applied external magnetic field of about 1.5 mT. Preferably, the core resistance is used for measuring external magnetic field values in the range of about 1.5 mT to about 7 T. In one embodiment, the core resistance is used for measuring external magnetic fields up to at least about 12 T. In one embodiment, the core resistance is used for measuring external magnetic fields up to at least about 30 T. In one embodiment, the signal induced in the pick-up coil is used for measuring external magnetic field values less than about 1.5 mT. In one embodiment, the signal induced in the pick-up coil is used for measuring the external magnetic field values in the range of about 0.1 nT to about 1.5 mT.

The magnetometer may further comprise a controller (described in further detail below) configured for receiving the magnetoresistance and induced signal measurements, and for outputting a value of the external magnetic field based on the received measurements.

According to other embodiments, the magnetometer may be configured to determine the external magnetic field values for magnetic fields less than a non-linear field of the pick-up coil, where the non-linear field is the field at which the pick-up coil signal begins to show a non-linear response. In that embodiment, the magnetoresistive measurements of the core are used for determining external magnetic fields greater than the non-linear field.

The magnetometer is further configured to measure the magnetic field gradient of an external magnetic field. The magnetometer may also comprise an additional pair of electrodes to measure the external magnetic field gradient. The magnetic field gradient measurements allow the measurement of small magnetic field changes on top of a slowly varying DC bias magnetic field. FIG. 2 shows an example of a magnetometer configuration that is suitable for gradient measurement using the two electrode pairs 908a,b. In one embodiment, three orthogonal core or pair of cores are provided for measuring the magnetic field and gradient vectors.

The magnetic field gradient measurements also allow the measurement of small magnetic field changes on top of a slowly varying DC bias magnetic field. This is particularly useful when the slowly varying DC bias magnetic field is greater than the saturation field of the core. Similar measurements are not possible with conventional fluxgate, giant magnetoresistance (GMR), anisotropic magnetoresistance (AMR), or tunnel magnetoresistance (TMR) magnetic field sensors due to saturation of the magnetization in the core or in the thin films.

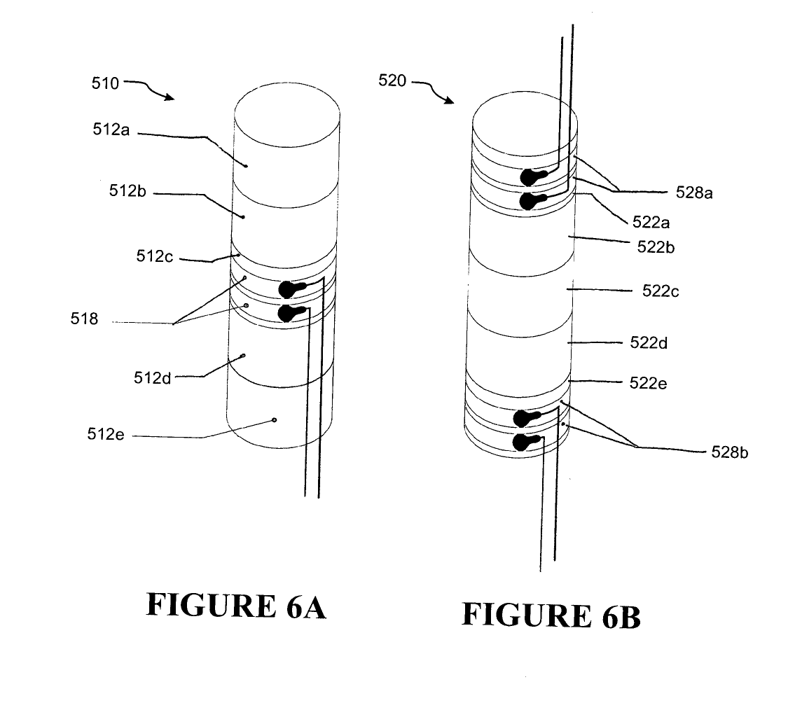

The magnetometer can be further configured to obtain better averaging of the magnetic field as shown in FIG. 6B. The magnetoresistance can be measured using the electrodes at 528a,b and the magnetic field determined from the R(B) function of the core. The magnetic fields measured by the electrodes can be averaged to determine the external magnetic field. In some embodiments, each core in the magnetometer comprises six electrodes, two electrodes positioned on each ends of the core and two electrodes positioned in the middle of the core, that are used for three magnetoresistance measurements. The three measurements provide better averaging of the magnetic field. Magnetic field gradient measurements can be done between cores.

In some embodiments, the magnetoresistive core, the pick-up coil, and the excitation coils may be components of a fluxgate magnetometer.

### Properties of the Core

The core comprises a material characterized by:
a high relative permeability that is greater than one and large, preferably above 100;
superparamagnetic behaviour where there is negligible magnetic remanence when a large applied magnetic field is reduced to zero; and
a magnetoresistive behaviour when a magnetic field is applied, and the magnetoresistance shows no saturation at high magnetic fields of at least 1 T.

The high permeability superparamagnetic magnetoresistive material exhibits a degree of electron spin polarization, and can comprise nanoparticles or nanopowder. In some embodiments, the core comprises the nanopowder or nanoparticles on or in an insulator to measure small magnetic fields. The nanoparticles could be dip coated on thin pressed sheets. Alternatively, the nanopowder could be incorporated into an insulating resin or polymer. The material may alternatively be in the form of nanotubes for example.

The nanoparticles (or nanopowder) exhibit electronic spin polarization where the magnetoresistance is negative and arises from spin tunneling between the nanoparticles in the range of operating temperatures. In one embodiment, the electron spin polarisation of the nanoparticles is about 100%.

Such a core comprising a high permeability superparamagnetic magnetoresistive material has negligible hysteresis, and negligible remnant magnetization. Thus, the core can be exposed to very high magnetic fields without being damaged or requiring degaussing, which is required for GMR, AMR, and MTJ sensors. The core can operate without the addition of a bias field (required for low field GMR sensing). In addition, the changes in the core resistance under an applied magnetic field allow the measurement of moderate to large magnetic fields.

In one embodiment, the relative permeability of the core is greater than 1. In other embodiments, the relative permeability is greater than 50. In preferred embodiments, the relative permeability is greater than 1000.

Superparamagnetism occurs in magnetic nanoparticles when the thermal energy is comparable or greater than the magnetocrystalline anisotropy energy. The core comprises a blocking temperature, above which there is negligible irreversibility and the magnetization follows the applied magnetic field (ie there is negligible hysteresis above the blocking temperature and the induction or magnetic flux density B(H)=μ₀(M+H) is a single valued function, where M is the magnetisation, H is the applied magnetic field, and μ₀ is the vacuum permeability). The blocking temperature is substantially below the operating temperature range and the Curie temperature is substantially above the operating temperature range. In a preferred embodiment, the blocking temperature of the core is below about 200 K and the Curie temperature is above about 313 K.

The size of the nanoparticles is directly related to the superparamagnetic properties. A value often given for superparamagnetic nanoparticles is a size of about 15 nm or less (which induces superparamagnetism down to 15 K or so for Fe for instance). The value depends on the materials and its nano/microstructure. A wide distribution of diameters can allow for superparamagnetism.

In some embodiments, the high permeability superparamagnetic magnetoresistive material comprises nanoparticles of a material chosen from the group consisting of iron, nickel, cobalt, their alloys and oxides, and mixtures thereof showing ferromagnetic behaviour at room temperature. In some embodiments, the material is chosen from the group consisting of FeNi, and FeCo. In preferred embodiments, the material comprises iron and/or iron oxide, such as iron (II, III) oxide (Fe₃O₄) for example. Fe₃O₄ is a preferred material as it exhibits a 100% electron spin polarization. Other examples of suitable materials include ferromagnetic ferrites. Ferrites include compounds with a stoichiometry following MFe₂O₄, MFeₓO_{y}, MNFe₂O₄ or MNFeₓO_{y} where M and N are cations (for example Zn, Mn, Ba, Ni, and Co). Examples of ferromagnetic ferrites include ZnFe₂O₄, BaFe₁₂O₉, and Ni_{0.5}Zn_{0.5}Fe₂O₄.

According to other embodiments, the core may comprise a mixture of two or more nanoparticles or nanopowders. According to further embodiments, nanoparticles or nanopowders may comprise a mixture of two or more materials.

The saturation of the core can be adjusted accordingly by changing the core composition. In some embodiments, the core can be designed such that the pick-up coil measurements can be used for large magnetic field measurements at the expense of increasing the minimum detectable field.

Embodiments of the magnetometer using the high permeability superparamagnetic magnetoresistive material described above in a pellet core construction and in a thin film construction will be described in further detail below. The high permeability superparamagnetic magnetoresistive material is not limited to these two constructions, and other constructions may be possible.

### Embodiment of a Magnetometer Using a Pellet Core

In some embodiments, the core comprises a pressed nanoparticle powder, where the nanoparticles comprise any of the materials described above. According to some embodiments, the pressed nanoparticle powder comprises a mixture of two or more nanoparticles. Other embodiments utilise nanoparticles that comprise two or more materials, such as core/shell nanoparticles. Suitable core/shell nanoparticles include Fe/Fe₃O₄ core/shell nanoparticles.

The nanoparticle powders can be synthesised by many different ways including chemical methods such as sol-gel synthesis, or physical methods such as ball-milling. To increase the material density, and therefore improve the conductivity and magnetization, the powder can be pressed into pellets. This step can be performed in different ways such as using a hydraulic press with a die and piston of the required size. Other suitable press systems that compress the powder so that the nanoparticles are in intimate contact and a stable solid is produced, such as for example a manual system can also be used. Also, depending on the dimension required for the core, one or several pellets might be required. The sensitivity of the core increases with the dimensions of the core. By way of example, increasing the number of turns in the pick-up coil would also increase the sensitivity. The dimensions are a compromise between the required sensitivities and dimensions for a particular application. For example, the core of the magnetometer shown in FIGS. 1, 2 and 4 for example comprises one pellet core, while the core of the magnetometer shown in FIGS. 3 and 6 comprises five stacked pellet cores.

Once the pellet core is formed, electrodes can be deposited on at least two places on the core and separated with a distance that is determined by the magnetoresistance requirements. The base resistance should be compatible with the associated electronics and the magnetoresistance should be high enough to match the need for applications. For the pressed pellets, the electrodes have to be close enough so that the resistance is relatively low and preferably less than about 1 mega-ohm. If the resistance is high enough to be comparable to the input impedance then the results will be unreliable. High resistances will also produce higher thermal noise voltages. Those persons skilled in the art will appreciate that the distance separating electrodes can be selected based on the resistivity of the core and the signal analysis electronics.

FIGS. 5A-D show different electrode configurations on a pellet. In some embodiments, the electrodes can also be embedded inside the pellet core as shown in FIG. 5E. The pellet could have lower level of compaction. In some embodiments, the contacts can be connected on the pellet, without the need for a deposited electrode. The different configurations shown in FIGS. 5A-E present different levels of complexity for the electrode deposition and setup of the magnetometer. FIG. 5A shows a more convenient pellet construction 410 with the electrodes 418 attached at one end of the core 412, and provides a low resistance. The electrodes 418 can be positioned in the middle of the core 412 where the magnetic core can be configured to act as a flux concentrator. The construction 420 shown in FIG. 5B is convenient for multiple attachments of electrodes 428 along the core 422. FIG. 5C shows a construction 430 for attachment of the electrodes 438 along the core 432 similar to FIG. 5B, but with a lower resistance. The construction 440 shown in FIG. 5D has the electrodes 448 positioned at either end of the core 442, and can be used if the resistivity is low. The construction 450 shown in FIG. 5E requires the core 452 to be moulded around the electrodes 458. Such a construction 450 provides a low resistance.

In one embodiment, the core is a rod made of pressed nanopowder pellets stacked on top of each other. At least one of the pellets contains two electrodes. In some preferred embodiments, the pellet with the electrodes for magnetoresistance measurements is located in the middle of the stack so as to benefit from the flux concentration of the other pellets.

FIGS. 6A and 6B show configurations including one or two electrode pairs for signal averaging where the electrode pairs are located in the centre (as shown in FIG. 6A) or near the ends (as shown in FIG. 6B). In these Figures, the core is made of a stack of pellets 512a-e and 522a-e, with at least one pellet (512c in FIG. 6A, and 522a and 522e in FIG. 6B) containing electrodes (518 in FIG. 6B, and 528a and 528b in FIG. 6B) for magnetoresistance measurements.

Providing several pairs of electrodes on different cores allows for the magnetic field gradient to be measured. Temporal drift in the resistance can be corrected for by using a Wheatstone bridge geometry where the reference arms are external to the region with the applied external magnetic field.

### Embodiment of a Film Magnetometer

In other embodiments, the core comprises a thin film containing nanoparticles comprising any of the materials described above.

Preferred cores comprise silicon dioxide and nanoparticles such as those described above. In preferred embodiments, the material comprises iron nanoparticles implanted in a silicon dioxide thin film on a silicon substrate.

The core is not limited to the design mentioned above. The core can also comprise a thin film comprising a granular medium. Examples of granular media showing magnetoresistance include granular Fe implanted into Al₂O₃, etc.

Such thin films may be prepared, for example, as described in International patent publication WO 2011/149366 filed on 27 May 2011 entitled ‘Magnetic Nanoclusters’ by the Institute of Geological and Nuclear Sciences Limited. The films may also be prepared by sputtering, deposition, cluster ion beams, and chemical reactions.

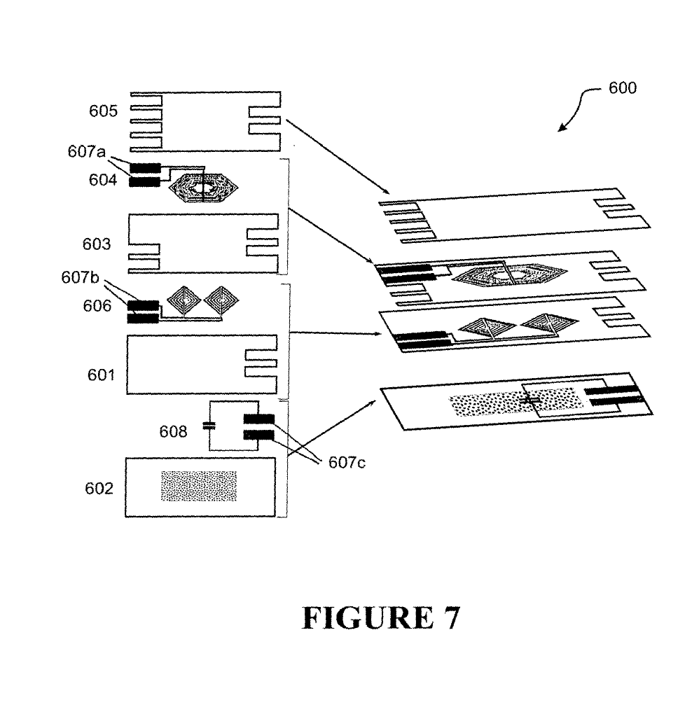

Planar magnetometers can be made in thin film form, which also allows for very small magnetic field sensors to be produced. An example film magnetometer 600 is shown in FIG. 7. The magnetometer 600 comprises a substrate and thin film 602 with superparamagnetic nanoparticles that has metal electrodes 608 for magnetoresistance measurements deposited onto the substrate and thin film 602. Successive deposition of insulating and metallic layers 601 and 603 can be used to fabricate planar excitation coils 606 and a pick-up coil 604. The planar coil geometry presented in FIG. 6 can be used to limit the number of microfabrication steps where the width of wire in the centre of each coil is smaller than that on the outside of the coil so that the current distribution is maintained. A final insulating layer 605 is deposited on top of the pick-up coil 604. Electrical contacts 607a, 607b, and 607c are made on metal pads that are not covered in the insulating layers.

In one embodiment, the planar excitation coils 606 and pick-up coil 604 are layered on the surface of a nanostructured substrate as mentioned above. This substrate comprises the superparamagnetic nanoparticles described above. However, if using ion implantation e-beam and annealing to fabricate the substrate, the nanoparticles are not deposited on the substrate but are formed in and/or on the substrate.

In another embodiment, the planar excitation coils 606 and the pick-up coil 604 are deposited on two different substrates and then pressed together.

In another embodiment, the high permeability superparamagnetic magnetoresistive material can be a thick film of pressed nanoparticles that is located in the centre of a stack containing planar excitation coils on one side and a pick-up coil on the other side.

In another embodiment, two sets of electrodes are deposited on the high permeability superparamagnetic magnetoresistive material, which enable two magnetoresistance measurements to be made and allows the magnetic field gradient to be measured.

In another embodiment, the core can be deposited or patterned so that the external magnetic field or the magnetic field gradient can be measured in two directions.

### Magnetometer as a Current Sensing Device

In another embodiment, the magnetometer comprising the thin film core shown in FIG. 7 may comprise an additional wire or coil so that the magnetometer can operate as a current sensor where the wire or coil is connected to the wire with the unknown current.

In another embodiment, a toroidal or ring core comprising the high permeability superparamagnetic magnetoresistive material can be used to measure current over a wide current range. This can be done by stacking the high permeability superparamagnetic magnetoresistive material in a toroidal form or filling a plastic container of the required shape.

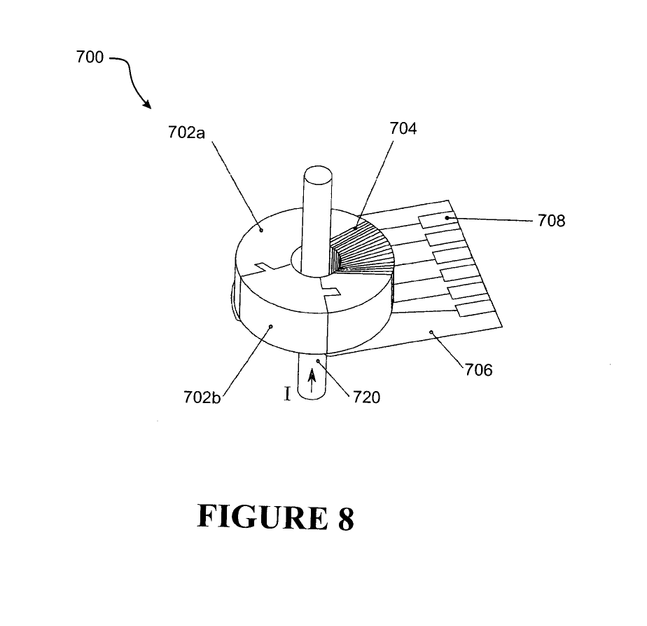

FIG. 8 illustrates such an embodiment of a magnetometer 700 comprising a main core 702a comprising a magnetic nanopowder, the pick-up coil and excitation coils 704, and a detachable core 702b that allows the current sensors to be placed around the wire 720 in which the current I is to be measured, and electrodes 708 to enable the external electronics for exciting and sensing to be attached. The detachable core 702b is removably engageable with the main core 702a. In this embodiment, the excitation coils are located below the pick-up coil. The electrical connections can be fabricated on a printed circuit board 706. The signal can be enhanced by winding loops of the wire containing the current to be measured around and through the core 702a.

In another embodiment, the detachable core 702b contains the magnetometer for measuring the unknown current. The core 702a and the detachable core 702b act as flux guides for the magnetic field generated by the current in the wire to be measured. The wire with the current to be measured can be wound around the main core 702a to increase the sensitivity.

In another embodiment, the wire with the current to be measured is wound around the two cores 902a and 902b in FIG. 2.

### The Controller

In some embodiments, the magnetometer comprises a controller for determining the external magnetic field based on measurements of the pick-up coil(s) and of the magnetoresistive core(s). In a preferred embodiment, the controller comprises a microcontroller. In other embodiments, the controller comprises a multiplexor.

One single output voltage from the magnetometer can be obtained, for example by using a battery as a stable voltage source and connecting the magnetoresistance electrodes to a Wheatstone bridge. The voltage difference will then be a function of the resistance and hence the magnetic field. The voltage difference can be used to measure moderate to high magnetic fields.

The output voltage from the pick-up coil can be connected to a lock-in amplifier and the output voltage from the lock-in amplifier can be used to measure low magnetic fields.

The output voltages from the lock-in amplifier and the Wheatstone bridge can be used as inputs into a microcontroller that can be programmed with the voltage to magnetic field tables for the lock-in amplifier and the Wheatstone bridge difference voltage. The microcontroller can be programmed so that it switches from the lock-in amplifier to the Wheatstone bridge signal at a field where the pick-up coil(s) signal loses its linearity and/or saturates and/or at a predetermined threshold value. The output from the microcontroller will then be a voltage that is proportional to the magnetic field.

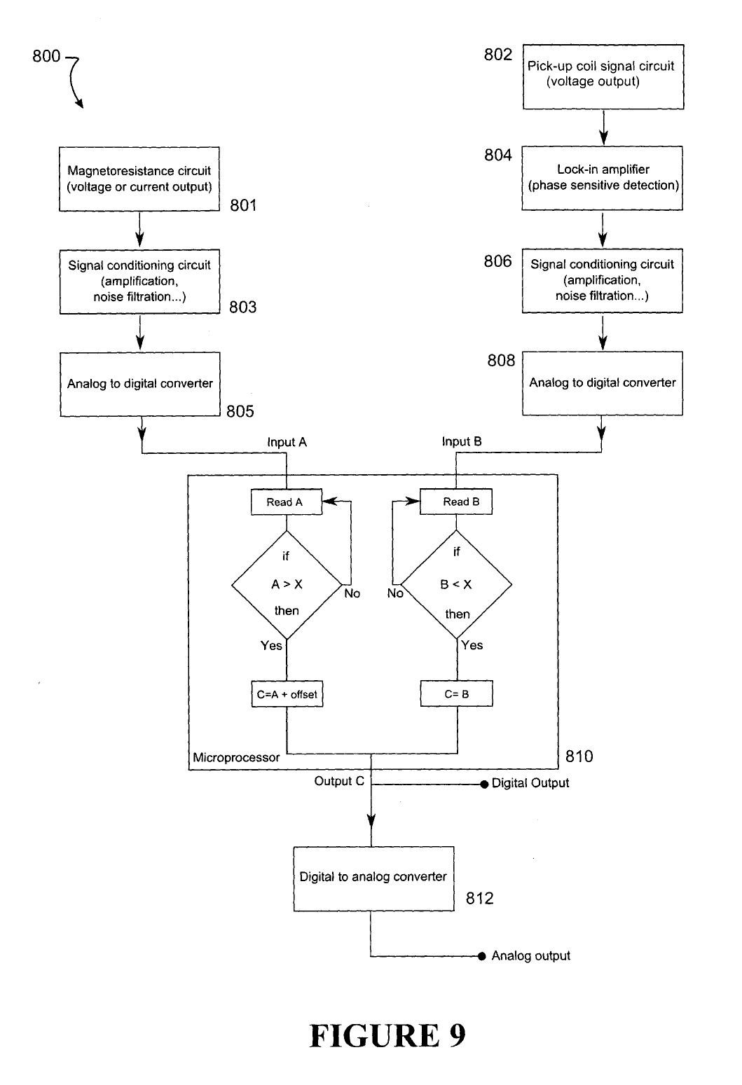

FIG. 9 illustrates such an embodiment 800 where the outputs from the magnetoresistance and lock-in amplifier are fed into a microcontroller 810. In some embodiments, these analogue signals are treated before the microcontroller 810 in order to provide amplified, noise filtered and/or digital conversion. The measurements from the magnetoresistive core(s) 801 are conditioned 803 to remove any noise and amplified accordingly before being converted into a digital signal using an analogue-to-digital converter 805. Similarly, the measurements from the pick-up coil 802 are communicated to a lock-in amplifier 804 for phase sensitive detection, after which the signal is conditioned 806 and converted into a digital signal using an analogue-to-digital converter 808. The digital representations of the measurements of the magnetoresistive core(s) and of the measurements of the signal from the pick-up coil(s) are input into the microcontroller 810 as inputs A and B respectively. The microcontroller 810 continuously reads these signals as inputs A and B and compares them to programmed values X and Y corresponding to threshold values for inputs A and B where X and Y are calibrated so that they correspond to the same measured magnetic field. In some embodiments, the values X and Y corresponds to the voltage values from the magnetoresistance and pick-up coil at the saturation field of the core. If input A is above X and input B is above Y then the microcontroller 810 will provide the input A value plus an offset as the output C. If input A is below X and input B is below Y then the microcontroller 810 will provide the input B value as the output C. In some embodiments, the output from the microcontroller can be digital and/or converted to an analogue signal using a digital-to-analogue converter 812.

The controller includes a processor which is configured to determine the external magnetic field. The processor may be any suitable computing device that is capable of executing a set of instructions that specify actions to be carried out. The term ‘computing device’ includes any collection of devices that individually or jointly execute a set or multiple sets of instructions to perform any one or more of the methods of determining the external magnetic field based on the signals from the pick-up coil and the magnetoresistance measurements.

The processor includes or is interfaced to a machine-readable medium on which is stored one or more sets of computer-executable instructions and/or data structures. The instructions implement one or more of the methods of determining the external magnetic field. The instructions may also reside completely or at least partially within the processor during execution. In that case, the processor comprises machine-readable tangible storage media.

The computer-readable medium is described in an example to be a single medium. This term includes a single medium or multiple media. The term ‘computer-readable medium’ should also be taken to include any medium that is capable of storing, encoding or carrying a set of instructions for execution by the processor and that cause the processor to perform the method of determining the external magnetic field. The computer-readable medium is also capable of storing, encoding or carrying data structures used by or associated with the instructions.

### Example 1a

### Fabrication of a Pellet Core

A mixed iron oxide nanopowder was obtained using an arc discharge method. The powder contained grains with multiple nanoparticles and it was filtered to ensure that the grain size was less than 60 μm. The pellets were prepared using a hydraulic press, 3 mm die/piston assembly and a pressure of about 3 tons.

Part of the powder was analysed using a SQUID magnetometer in order to determine its magnetic properties and the results are shown in FIG. 10. The powder showed a saturation magnetization of about 72 emu/g, which is consistent with Fe₂O₃ and Fe₃O₄. The magnetization showed no hysteresis within the limit of detectability, which is consistent with the majority of the material being superparamagnetic.

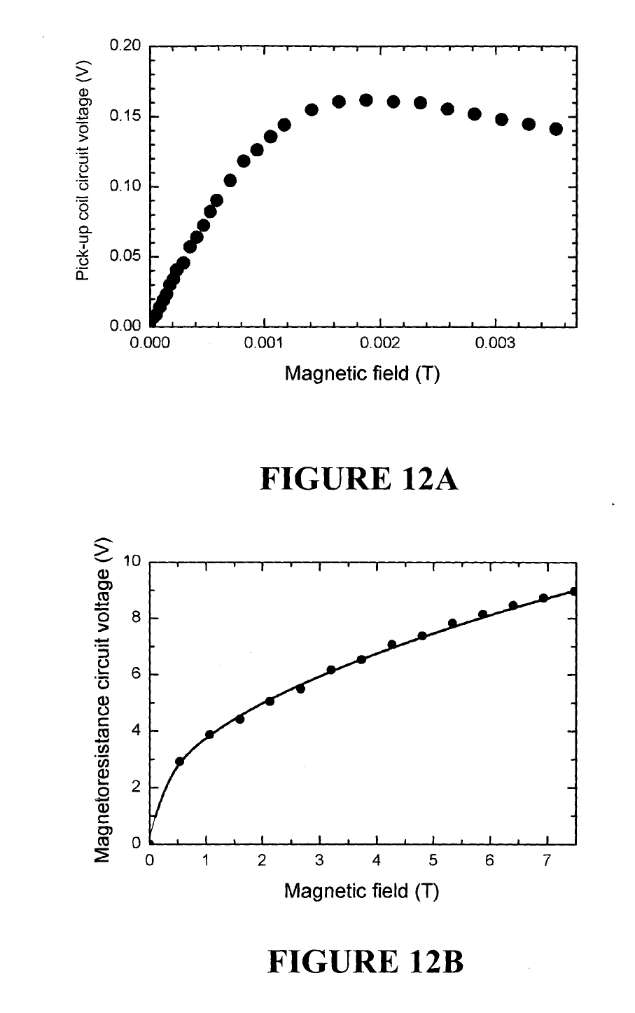

Cores were made with a diameter of 3 mm and a length of 8 mm by stacking pressed pellets that were about 1 mm thick. Two electrodes were deposited on to the last pellet in a configuration similar to that shown in FIG. 5a. The gap between the electrodes was about 1 mm. The resistance measured across those two electrodes was about 40 kΩ at room temperature. The magnetoresistance is plotted in FIG. 12b where the experimental data is given as points and the fitting using the spin-polarised tunneling theoretical model known in the art [E. K. Hemery et al. Physica B 390 (2007) 175-178].

### Example 1b

### Fabrication of a Thin Film Core

A core for a planar magnetometer was also fabricated by ion beam synthesis. Iron atoms were implanted in SiO₂ on a Si substrate with an energy of 15 keV and a fluence of 1×10¹⁶ ions cm⁻², followed by electron beam annealing at 1000° C. for two hours. A 8 mm×4 mm sample was obtained. Two electrical contacts were fabricated on the film by depositing a 2 nm thick titanium layer followed by a 20 nm thick aluminium layer using a high vacuum vapour deposition system. The dimensions of the electrodes are 4 mm×3 mm square and the gap between the electrodes was 1 mm. The titanium layer was used to improve the adhesion and electrical contact between the aluminium and the magnetic material. The samples were annealed in vacuum at 300° C. for 30 minutes to further improve the contact resistance. The magnetoresistance is plotted in FIG. 10 for a current of 0.01 mA.

### Example 2

### Wide Dynamic-Range Measurement with a Magnetometer

Cylindrical cores were fabricated from iron oxide nanopowder and were then pressed as described in the previous example 1a and then inserted in a hollow plastic tube with the excitation coils and pick-up coil wound around it. The excitation coils were made of 0.05 mm insulated copper wire with 275 turns each, and positioned in the same configuration as shown in FIG. 3. Thin plastic adhesive tape was used to separate the excitation and pick-up coils. The pick-up coil was wound over the excitation coils in a manner similar to that shown in FIG. 3. The wire for this coil had a diameter of 0.1 mm wire and there was 200 turns.

The excitation frequency was 40 kHz. The signal from the pick-up coil was measured using homebuilt electronics that contained a lock-in amplifier. The magnetoresistance signal was measured using a stable current source and the current was measured using a voltmeter. The system was tested in a wire-wound solenoid magnet with magnetic fields from 1 mT to 20 mT without magnetic shielding where the magnetic field was measured using a Hall sensor. From 0.01 mT to 8 T the system was tested using the AC transport mode of a Quantum Design Inc. Physical Properties Measurement System.

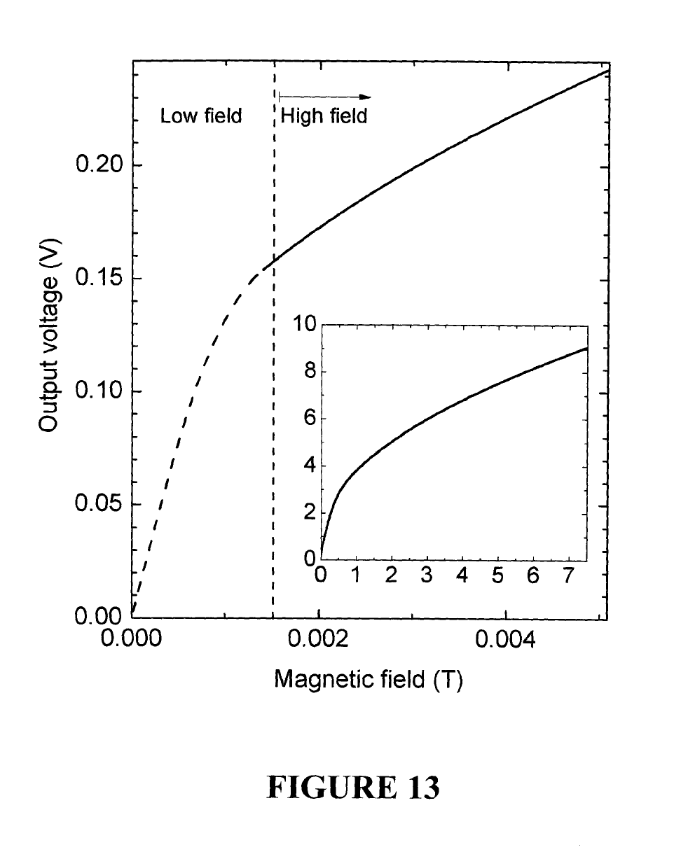

The resultant pick-up coil voltage and magnetoresistance are plotted in FIGS. 12A and 12B. It can be seen that low magnetic fields can be measured using the pick-up coils and moderate to high magnetic fields can be measured using the magnetoresistance signal. FIG. 13 shows the simulated response from a microcontroller with a threshold corresponding to a field of 1.5 mT, gains and offsets providing a monotonic response between 0 and 10 V. The dashed curve shows the processed signal from the pick-up coil while the solid curve shows the processed signal from the fitted magnetoresistance measurement.

It is not the intention to limit the scope of the invention to the abovementioned examples only. As would be appreciated by a skilled person in the art, many variations are possible without departing from the scope of the invention as set out in the accompanying claims.

What we claim is:

1. A magnetometer for measuring an external magnetic field, comprising:
at least one core having a magnetoresistance property being measurable in response to the external magnetic field;
at least one excitation coil near or around the core or at least one of the cores, the excitation coil(s) being configured to be driven by an alternating current to partially saturate a magnetisation of the core(s) during part of the AC cycle; and
at least one pick-up coil near or around at least a portion of the core(s) and the excitation coil(s), the pick-up coil(s) being configured to carry a signal induced at least in the presence of the external magnetic field, the induced signal being measurable in response to the external magnetic field.

2. The magnetometer of claim 1, wherein the core(s) comprise(s) a high permeability superparamagnetic magnetoresistive material comprising nanoparticles, and the material exhibits electron spin polarisation for negative magnetoresistances, which arises from spin tunneling between nanoparticles over a range of operating temperatures.

3. The magnetometer of claim 2, wherein the high permeability superparamagnetic magnetoresistive material comprises nanoparticles chosen from the group consisting of iron, nickel, cobalt, their alloys and oxides, and mixtures thereof showing ferromagnetic behaviour at room temperature.

4. The magnetometer of claim 2 or 3, wherein the high permeability superparamagnetic magnetoresistive material comprises nanoparticles of a ferromagnetic ferrite.

5. The magnetometer of claim 4, wherein the ferromagnetic ferrite is chosen from the group consisting of ZnFe₂O₄, BaFe₁₂O₉, and Ni_{0.5}Zn_{0.5}Fe₂O₄.

6. The magnetometer of claim 2 or 3, wherein the core(s) comprise(s) pressed nanoparticle powder.

7. The magnetometer of claim 6, wherein the pressed nanoparticle powder comprises core/shell nanoparticles.

8. The magnetometer of claim 6, wherein the pressed nanoparticle powder comprises iron (II, III) oxide nanoparticles.

9. The magnetometer of any one of claims 1 to 8, wherein at least one core is a toroidal-shaped core.

10. The magnetometer of any one of claims 1 to 8, wherein at least one core is a circular-, elliptical- or rectangular-shaped core.

11. The magnetometer of any one of claims 1 to 8, wherein at least one core is a substantially cross-shaped core and the magnetometer comprises four excitation coils, each excitation coil around or near a respective arm of the cross-shaped core.

12. The magnetometer of claim 2 or 3, wherein the core(s) comprise(s) a magnetoresistive film containing nanoparticles.

13. The magnetometer of claim 12, wherein the nanoparticles are synthesised on or embedded in a surface of a substrate of the film.

14. The magnetometer of claim 12 or 13, wherein the film comprises silicon dioxide and iron nanoparticles.

15. The magnetometer of any one of claims 1 to 14, wherein the core(s) comprise(s) a blocking temperature substantially below an operating temperature range and a Curie temperature substantially above the operating temperature range.

16. The magnetometer of claim 15, wherein the blocking temperature of the core(s) is below about 200 K and the Curie temperature of the core(s) is above about 313 K.

17. The magnetometer of any one of claims 1 to 16, wherein a relative permeability of the core(s) is greater than 1.

18. The magnetometer of claim 17, wherein the relative permeability of the core(s) is greater than 50.

19. The magnetometer of claim 18, wherein the relative permeability of the core(s) is greater than 1000.

20. The magnetometer of any one of claims 1 to 19, wherein the signal from the pick-up coil(s) is used for measuring external magnetic fields below a defined magnetic field threshold and the magnetoresistance of the core(s) is used for measuring external magnetic fields above the defined magnetic field threshold.

21. The magnetometer of claim 20, wherein the defined magnetic field threshold is a saturation field of the pick-up coil(s), which is the field at which the signal from the pick-up coil(s) begins to show a saturated response, and the pick-up coil(s) has/have a substantially linear and non-linear response up to the saturation field.

22. The magnetometer of claim 21, wherein the defined magnetic field threshold is about 1.5 mT.

23. The magnetometer of claim 20, wherein the defined magnetic field threshold is the non-linear field, which is the field at which the signal from the pick-up coil(s) switches from a substantially linear response to a non-linear response.

24. The magnetometer of claim 23, wherein the signal from the pick-up coil(s) is linear with less than 1% non-linearity up to about 0.5 mT, and the defined magnetic field threshold is about 0.5 mT.

25. The magnetometer of any one of claims 1 to 24, wherein the signal from the pick-up coil(s) is used for measuring external magnetic field values down to about 0.1 nT.

26. The magnetometer of any one of claims 1 to 25, wherein the magnetoresistance of the core(s) is used for measuring external magnetic field values up to at least about 7 T.

27. The magnetometer of claim 26, wherein the magnetoresistance of the core(s) is used for measuring external magnetic field values up to at least about 12 T.

28. The magnetometer of claim 27, wherein the magnetoresistance of the core(s) is used for measuring external magnetic field values up to at least about 30 T.

29. The magnetometer of any one of claims 1 to 28, wherein the magnetometer comprises a fluxgate arrangement, wherein the core(s), two or more excitation coils and the pick-up coil(s) are components of the fluxgate arrangement.

30. The magnetometer of any one of claims 1 to 29, comprising two or more excitation coils, each excitation coil near or around opposite ends of the core or near or around a respective core.

31. The magnetometer of claim 30, wherein the excitation coils are configured to induce a substantially negligible total magnetisation of the core(s) in an absence of the external magnetic field.

32. The magnetometer of claim 31, wherein the magnetometer comprises two excitation coils, which are configured to induce two synchronous anti-parallel alternating magnetic fields in regions of the core(s) surrounded by or near each excitation coil.

33. The magnetometer of claim 30, wherein the excitation coils are configured to induce an alternating magnetisation of the core(s) in an absence of the external magnetic field.

34. The magnetometer of claim 33, wherein the excitation coils are configured to induce a signal in the pick-up coil(s) that comprises positive and negative responses, and the external magnetic field results in a change in time interval between the negative and positive responses in the induced signal.

35. The magnetometer of claim 33, wherein the excitation coils are configured to induce a signal in the pick-up coil(s) that comprises a series of pulses, and a change in peak voltage of one or more of the pulses represents the external magnetic field.

36. The magnetometer of any one of claims 30 to 35, comprising one core and two excitation coils, each excitation coil near or around opposite ends of the core.

37. The magnetometer of any one of claims 30 to 35, comprising a first core, a second core, a first excitation coil and a second excitation coil, wherein the first excitation coil is near or around the first core and the second excitation coil is near or around the second core.

38. The magnetometer of any one of claims 30 to 35, comprising a first core, a second core, a first pair of excitation coils and a second pair of excitation coils, wherein first pair of excitation coils are near or around opposite ends of one of the first core and the second pair of excitation coils are near or around opposite ends of the second core.

39. The magnetometer of claim 37 or 38, wherein in the absence of an external magnetic field, a magnetic field induced by the excitation coil(s) near or around the first core is opposite to a magnetic field induced by the excitation coil(s) near or around the second core, a sum of the magnetic fields in the first and second core being substantially zero in the absence of an external magnetic field, wherein the external magnetic field results in the sum of the magnetic fields in the first and second core being non-zero and time-varying.

40. The magnetometer of any one of claims 30 to 35, comprising three cores and six excitation coils for magnetic field measurements in three axes, a respective pair of excitation coils around or near one of the respective cores, wherein the cores are positioned orthogonally to each other core and magnetic field measurements from the core in an axis represent the external magnetic field in that axis.

41. The magnetometer of any one of claims 30 to 35, comprising six cores and twelve excitation coils for magnetic field measurements in three axes, wherein two excitation coils are around or near each of the cores, wherein three pairs of cores are positioned orthogonally to each other pair and magnetic field measurements from two respective cores in an axis represent the external magnetic field in that axis.

42. The magnetometer of any one of claims 1 to 41, comprising a plurality of pick-up coils, wherein each pick-up coil is near or around different portions of the core(s) and the excitation coil(s).

43. The magnetometer of any one of claims 1 to 42, wherein the excitation coil(s) is/are driven with an alternating current to induce fields that drive at least one core into saturation during part of the AC cycle having a peak current about 1 pA to about 5 A and a frequency greater than about 10 kHz.

44. The magnetometer of any one of claims 1 to 43, comprising a pair of electrodes electrically coupled to the core or a respective one of the cores to measure magnetoresistance of the core(s).

45. The magnetometer of claim 44, wherein the electrodes are electrically connected to a Wheatstone bridge arrangement for generating a voltage difference that is indicative of the external magnetic field.

46. The magnetometer of any one of claims 1 to 43, comprising more than one pair of electrodes electrically coupled to the core(s), the pairs being arranged to measure a magnetic field gradient of the external magnetic field and/or each or at least one pair being configured to measure the magnetoresistance of the core(s).

47. The magnetometer of any one of claims 1 to 46, wherein a wire for carrying a current is placed proximate to at least one core, and the current carried by the wire is determined by measuring the external magnetic field resulting from the current flowing through the wire.

48. The magnetometer of claim 47, wherein the wire for carrying the current is wound around or placed through at least one core.

49. The magnetometer of any one of claims 1 to 48, wherein the magnetometer comprises a controller configured to:
receive magnetoresistance measurements from the core(s);
receive measurements of the induced signal from the pick-up coil(s); and
determine the external magnetic field based on the magnetoresistance measurements and/or measurements of the induced signal from the pick-up coil(s).

50. The magnetometer of claim 49, wherein the controller is configured to determine the external magnetic field based on at least the magnetoresistive measurements where the external magnetic field is sufficient to saturate at least one core.

51. The magnetometer of claim 40, wherein the controller is configured to determine the external magnetic field based on at least measurements of the induced signal from the pick-up coil(s) where the external magnetic field does not substantially saturate the core(s).

52. The magnetometer of any one of claims 49 to 51, wherein the controller is configured to determine the external magnetic field based on at least the magnetoresistive measurements when sensitivity of measurements of the induced signal in the pick-up coil(s) falls below a threshold.

53. The magnetometer of claim 52, wherein the threshold is lower than a magnetic field that saturates at least one core.

54. The magnetometer of any one of claims 49 to 53, wherein the controller comprises a multiplexor circuit arrangement for outputting one of the external magnetic field measurements based on the magnetoresistance and the external magnetic field measurements based on the induced signal depending on sensitivity of the induced signal measurements in the pick-up coil(s).

55. A method of measuring an external magnetic field using a magnetometer of claim 1, the method comprising:
(a) using the signal from the pick-up coil(s) for measuring external magnetic fields below a defined magnetic field threshold; and
(b) using the magnetoresistance of the core(s) for measuring external magnetic fields above the defined magnetic field threshold.

56. The method of claim 55, wherein the defined magnetic field threshold is a saturation field of the pick-up coil(s), which is the field at which the signal from the pick-up coil(s) begins to show a saturated response, and the signal from the pick-up coil(s) has a substantially linear and non-linear response up to the saturation field.

57. The method of claim 56, wherein the defined magnetic field threshold is about 1.5 mT.

58. The method of claim 55, wherein the defined magnetic field threshold is the non-linear field, which is the field at which the signal from the pick-up coil(s) switches from a linear response to a non-linear response.

59. The method of claim 58, wherein the signal from the pick-up coil(s) is linear with less than 1% non-linearity up to about 0.5 mT, and the defined magnetic field threshold is about 0.5 mT.

60. The method of any one of claims 55 to 59, wherein step (a) comprises using the signal from the pick-up coil(s) for measuring external magnetic field values down to about 0.1 nT.

61. The method of any one of claims 55 to 60, wherein step (b) comprises using the magnetoresistance of the core(s) for measuring external magnetic field values up to at least about 7 T.

62. The method of claim 61, wherein step (b) comprises using the magnetoresistance of the core(s) for measuring external magnetic field values up to at least about 12 T.

63. The method of claim 62, wherein step (b) comprises using the magnetoresistance of the core(s) for measuring external magnetic field values up to at least about 30 T.

64. The method of any one of claims 55 to 63, wherein the magnetometer comprises two excitation coils, and the method further comprises using the excitation coils to induce two anti-parallel or parallel alternating fields in regions of the core(s) covered by each excitation coil.

65. The method of any one of claims 55 to 64, further comprising driving the excitation coils with an alternating current to induce fields that saturate at least one core during part of the AC cycle of about 1 pA to about 5 A and at a frequency greater than about 10 kHz.

66. The method of any one of claims 55 to 65, further comprising placing a wire for carrying a current proximate to the core(s) for measuring the external magnetic field resulting from the current flowing through the wire.

67. The method of claim 66, comprising winding the wire around or placing the wire through at least one core.

68. A method of assembling a magnetometer, the method comprising the steps of:
(a) electrically coupling electrodes to one of at least one magnetoresistive core;
(b) winding at least one excitation coil near or around at least part of the core(s); and
(c) winding at least one pick-up coil near or around the excitation coil(s) and the core(s).

69. The method of claim 68, wherein at least one magnetoresistive core comprises a high permeability superparamagnetic magnetoresistive material comprising nanoparticles, and the material exhibits electron spin polarisation for negative magnetoresistances, which arises from spin tunneling between nanoparticles over a range of operating temperatures.

70. The method of claim 69, wherein the high permeability superparamagnetic magnetoresistive material comprises nanoparticles chosen from the group consisting of iron, nickel, cobalt, their alloys and oxides, and mixtures thereof showing ferromagnetic behaviour at room temperature.

71. The method of claim 69 or 70, wherein the high permeability superparamagnetic magnetoresistive material comprises nanoparticles of a ferromagnetic ferrite.

72. The method of claim 71, wherein the ferromagnetic ferrite is chosen from the group consisting of ZnFe₂O₄, BaFe₁₂O₉, and Ni_{0.5}Zn_{0.5}Fe₂O₄.

73. The method of claim 69 or 70, wherein the core(s) comprise(s) a pressed nanoparticle powder.

74. The method of claim 73, wherein the pressed nanoparticle powder comprises core/shell nanoparticles.

75. The method of claim 73, wherein the pressed nanoparticle powder comprises iron (II, III) oxide nanoparticles.

76. The method of any one of claims 68 to 75, wherein at least one core is a toroidal shaped core.

77. The magnetometer of any one of claims 65 to 75, wherein at least one core is a circular-, elliptical- or rectangular-shaped core.

78. The method of any one of claims 68 to 75, wherein at least one core is a substantially cross-shaped core and the method comprises winding at least one excitation coil around each arm of the cross-shaped core.

79. The method of any one of claims 68 to 78, wherein at least one magnetoresistive core is a pellet core, and step (a) comprises electrically coupling the electrodes to an end of the pellet core.

80. The method of any one of claims 68 to 78, wherein at least one magnetoresistive core is a pellet core, and step (a) comprises electrically coupling the electrodes along a length of the pellet core.

81. The method of any one of claims 68 to 78, wherein at least one magnetoresistive core is a pellet core, and step (a) comprises electrically coupling the electrodes along a cross sectional area of the pellet core.

82. The method of any one of claims 68 to 78, wherein at least one magnetoresistive core is a pellet core, and step (a) comprises electrically coupling the electrodes to opposite ends of the pellet core.

83. The method of any one of claims 68 to 78, wherein at least one magnetoresistive core is a pellet core, and the method further comprises moulding the pellet core around the electrodes.

84. The method of any one of claims 68 to 78, further comprising stacking a plurality of magnetoresistive cores to form a column of cores.

85. The method of claim 84, wherein step (a) comprises electrically coupling electrodes to the core substantially in the middle of the column of cores.

86. The method of claim 84 or 85, wherein step (a) comprises electrically coupling electrodes to the core at an end of the column of cores.

87. The method of any one of claims 84 to 86, wherein step (a) comprises electrically coupling electrodes to cores at opposite ends of the column of cores.

88. The method of claim 69 or 70, wherein the core(s) comprise(s) a magnetoresistive film containing nanoparticles.

89. The method of claim 88, further comprising synthesising or embedding the nanoparticles on or in a surface of a substrate of the film.

90. The method of claim 88 or 89, wherein the film comprises silicon dioxide and iron nanoparticles.

91. The method of any one of claims 68 to 90, wherein the core(s) comprise(s) a blocking temperature substantially below an operating temperature range and a Curie temperature substantially above the operating temperature range.

92. The method of claim 91, wherein the blocking temperature of the core(s) is below about 200 K and the Curie temperature of the core(s) is above about 313 K.

93. The method of any one of claims 68 to 92, wherein a relative permeability of the core(s) is greater than 1.

94. The method of claim 93, wherein the relative permeability of the core(s) is greater than 50.

95. The method of claim 96, wherein the relative permeability of the core(s) is greater than 1000.

96. The method of any one of claims 68 to 95, wherein the electrodes are configured to measure a magnetoresistance of the core(s), the magnetoresistance and a signal carried by the pick-up coil(s) being measurable in response to an external magnetic field.

97. The method of any one of claims 68 to 95, wherein the magnetometer comprises two or more excitation coils, and the excitation coils are configured to be driven by an alternating current to partially saturate a magnetisation of the core(s) during part of the AC cycle.

98. The method of any one of claims 68 to 97, wherein step (a) comprises electrically connecting the electrodes to a Wheatstone bridge arrangement, the Wheatstone bridge arrangement being configured to generate a voltage difference that is indicative of external magnetic field.

99. The method of any one of claims 68 to 98, wherein step (a) comprises electrically coupling a plurality of pairs of electrodes to the core(s), the pairs being arranged to measure a magnetic field gradient of the external magnetic field and/or each or at least one pair being configured to measure the magnetoresistance of the core(s).

100. The method of any one of claims 68 to 99, further comprising electrically coupling the electrodes and the pick-up coil to a controller, wherein the controller is configured to:
receive magnetoresistance measurements from the core(s);
receive measurements of the induced signal from the pick-up coil(s); and
determine the external magnetic field based on the magnetoresistance measurements and/or measurements of the induced signal from the pick-up coil(s).

101. The method of any one of claims 68 to 99, wherein the magnetometer comprises three cores and six excitation coils for magnetic field measurements in three axes, wherein the method further comprises locating a respective pair of excitation coils around or near one of the respective cores, wherein the cores are located orthogonally to each other core, and magnetic field measurements from the core in an axis represent the magnetic field in that axis.

102. The method of any one of claims 68 to 100, wherein the magnetometer comprises six cores and twelve excitation coils for magnetic field measurements in three axes, wherein the method comprises locating two excitation coils around or near each of the cores, and magnetic field measurements from two respective cores represent the external magnetic field in a respective one of the three axes, wherein three pairs of cores are located orthogonally to each other pair, and magnetic field measurements from two respective cores in the axis represent the magnetic field in that axis

103. The method of any one of claims 68 to 102, wherein the magnetometer comprises a plurality of pick-up coils, and the method comprises positioning each pick-up coil near or around different portions of the core and the excitation coil(s).

104. A method for assembling a magnetometer, the method comprising the steps of:
(a) depositing different metallic layers in the shape of planar coils separated by insulating layers onto one or more substrates containing superparamagnetic nanoparticles;
(b) electrically coupling electrodes to the substrate(s) containing superparamagnetic nanoparticles.

105. The method of claim 104, wherein the superparamagnetic nanoparticles form a magnetoresistive material that exhibits electron spin polarisation for negative magnetoresistances, which arises from spin tunneling between nanoparticles over a range of operating temperatures.

106. The method of claim 104 or 105, wherein the superparamagnetic nanoparticles are chosen from the group consisting of iron, nickel, cobalt, their alloys and oxides, and mixtures thereof showing ferromagnetic behaviour at room temperature.

107. The method of any one of claims 104 to 106, wherein the superparamagnetic nanoparticles comprise a ferromagnetic ferrite.

108. The method of claim 107, wherein the ferromagnetic ferrite is chosen from the group consisting of ZnFe₂O₄, BaFe₁₂O₉, and Ni_{0.5}Zn_{0.5}Fe₂O₄.

109. The method of any one of claim 105 or 106, wherein superparamagnetic nanoparticles comprise core/shell nanoparticles.

110. The method of claim 105 or 106, wherein the superparamagnetic nanoparticles comprise iron (II, III) oxide nanoparticles.

111. The method of any one of claims 104 to 110, wherein the substrates containing superparamagnetic nanoparticles are a film.

112. The method of claim 111, wherein the film comprises silicon dioxide and iron nanoparticles.

113. The method of any one of claims 104 to 112, wherein the superparamagnetic nanoparticles form a material comprising a blocking temperature substantially below an operating temperature range and a Curie temperature substantially above the operating temperature range.

114. The method of claim 113, wherein the blocking temperature of the core(s) is below about 200 K and the Curie temperature of the core(s) is above about 313 K.

115. The method of any one of claims 104 to 114, wherein the superparamagnetic nanoparticles form a material that has a relative permeability greater than 1.

116. The method of claim 115, wherein the relative permeability is greater than 50.

117. The method of claim 116, wherein the relative permeability is greater than 1000.

118. The method of any one of claims 104 to 117, further comprising synthesising or embedding the superparamagnetic nanoparticles on or in a surface of the substrate.

119. The method of any one of claims 104 to 118, wherein the electrodes are configured to measure a magnetoresistance and one of the planar coils is a pick-up coil, the magnetoresistance and a signal carried by the pick-up coil being measurable in response to external magnetic fields.

120. The method of any one of claims 104 to 119, wherein two planar coils are excitation coils and are configured to induce magnetic fields in the substrates containing superparamagnetic nanoparticles.

121. The method of any one of claims 104 to 120, wherein step (a) comprises electrically connecting the electrodes to a Wheatstone bridge arrangement, and the Wheatstone bridge being configured to generate a voltage difference that is indicative of external magnetic fields.

122. The method of any one of claims 104 to 121, wherein step (a) comprises electrically coupling a plurality of pairs of electrodes to the core(s), the pairs being arranged to measure a magnetic field gradient of the external magnetic field and/or each or at least one pair being configured to measure the magnetoresistance of the substrates containing superparamagnetic nanoparticles.

123. The method of any one of claims 104 to 122, further comprising electrically coupling the electrodes and at least one planar coil to a controller, wherein the controller is configured to:
receive magnetoresistance measurements from the core(s);
receive measurements of a signal from the at least one planar coil, the signal being induced in the presence of external magnetic fields; and
determine the external magnetic fields based on the magnetoresistance measurements and/or measurements of the induced signal from the planar coil.

124. The method of any one of claims 104 to 123, wherein step (a) comprises locating planar excitation coils and planar pick-up coils on different substrates, and assembling the planar excitation coils and planar pick-up coils with the substrate containing superparamagnetic nanoparticles.

125. A magnetometer when assembled by the method of any one of claims 68 to 124.
